(19) United States
(12) Patent Application Publication
(10) Pub. No.: US 2025/0194105 A1
(43) Pub. Date: Jun. 12, 2025

(54) MAGNETIC MEMORY DEVICE

(71) Applicant: Samsung Electronics Co., Ltd., Suwon-si (KR)

(72) Inventors: Yongjae Lee, Suwon-si (KR); Kyen-Hee Lee, Suwon-si (KR); Jinmyoung Lee, Suwon-si (KR)

(21) Appl. No.: 18/740,813

(22) Filed: Jun. 12, 2024

(30) Foreign Application Priority Data
Dec. 7, 2023 (KR) 10-2023-0177073

(51) Int. Cl. H10B 61/00

(52) U.S. Cl. CPC H10B 61/22

(57) ABSTRACT

A magnetic memory device includes a substrate having top and bottom surfaces, a first active region on the top surface of the substrate, the first active region including a lower channel pattern and a lower source/drain pattern, a second active region stacked on the first active region, the second active region including an upper channel pattern and an upper source/drain pattern, a gate electrode on the lower and upper channel patterns and extending in a first direction, a lower interconnection layer on the bottom surface of the substrate, a magnetic tunnel junction pattern and a spin-orbit torque line in the lower interconnection layer, a first lower contact electrically connecting the lower source/drain pattern to the magnetic tunnel junction pattern, and a second lower contact electrically connecting the upper source/drain pattern to the spin-orbit torque line.

### CROSS-REFERENCE TO RELATED APPLICATIONS

This U.S. non-provisional patent application claims priority under 35 U.S.C. § 119 to Korean Patent Application No. 10-2023-0177073, filed on Dec. 7, 2023, in the Korean Intellectual Property Office, the entire contents of which are hereby incorporated by reference.

### BACKGROUND

The present disclosure relates generally to a magnetic memory device, and in particular, to a spin-orbit-torque-based magnetic memory device.

As the demand for electronic devices with increased speed and/or reduced power consumption increases, the demand for semiconductor memory devices with faster operating speeds and/or lower operating voltages is increasing. A magnetic memory device has been proposed to satisfy such a demand. Due to their high speed operation and/or nonvolatility, magnetic memory devices are emerging as a promising alternative to traditional semiconductor memory devices.

In general, the magnetic memory device includes a magnetic tunnel junction (MTJ) pattern. The MTJ pattern includes two magnetic layers and an insulating layer interposed therebetween. Resistance of the MTJ pattern may vary depending on magnetization directions of the magnetic layers relative to one another. For example, the electrical resistance of the MTJ pattern is higher when magnetization directions of the magnetic layers are anti-parallel to each other compared to when they are parallel to each other. Such a difference in electrical resistance can be detected and used for data storing/reading operations of the magnetic memory device. As the electronics industry advances, there is a growing demand for magnetic memory devices with higher integration density and lower power consumption properties. Thus, more research is still needed to satisfy such a demand.

### SUMMARY

An embodiment of the inventive concept provides a spin-orbit-torque-based magnetic memory device that can be easily integrated.

According to an embodiment of the inventive concept, a magnetic memory device may include a substrate having a top surface and a bottom surface, which are opposite to each other, a first active region on the top surface of the substrate, the first active region including a lower channel pattern and a lower source/drain pattern connected to the lower channel pattern, a second active region stacked on the first active region, the second active region including an upper channel pattern and an upper source/drain pattern connected to the upper channel pattern, a gate electrode provided on the lower and upper channel patterns and extended in a first direction, a lower interconnection layer on the bottom surface of the substrate, a magnetic tunnel junction pattern and a spin-orbit torque (SOT) line in the lower interconnection layer, a first lower contact provided to penetrate (i.e., extend at least partially into) a portion of the lower interconnection layer and the substrate and connect the lower source/drain pattern to the magnetic tunnel junction pattern, and a second lower contact provided to penetrate a portion of the lower interconnection layer, the substrate, and the lower source/drain pattern and connect the upper source/drain pattern to the spin-orbit torque line.

According to an embodiment of the inventive concept, a magnetic memory device may include a substrate having a top surface and a bottom surface, which are opposite to each other, a lower source/drain pattern on the top surface of the substrate, an upper source/drain pattern stacked on the lower source/drain pattern and vertically spaced apart from the lower source/drain pattern, the lower and upper source/drain patterns being at least partially vertically overlapped with each other, an interlayer insulating layer covering (i.e., on or over) the lower and upper source/drain patterns, a source line on the interlayer insulating layer, a lower interconnection layer on the bottom surface of the substrate, a magnetic tunnel junction pattern and a spin-orbit torque line disposed in the lower interconnection layer, and a bit line disposed in the lower interconnection layer and spaced apart from the bottom surface of the substrate with the magnetic tunnel junction pattern and the spin-orbit torque line interposed therebetween. The source line and the bit line may be spaced apart from each other in a first direction and may be extended in a second direction crossing the first direction, when viewed in a plan view. The spin-orbit torque line may be extended in the second direction and may be at least partially vertically overlapped with the bit line.

According to an embodiment of the inventive concept, a magnetic memory device may include a substrate having a top surface and a bottom surface, which are opposite to each other, and including an active pattern, a first active region on the active pattern, the first active region including a lower channel pattern and a lower source/drain pattern connected to the lower channel pattern, a second active region stacked on the first active region, the second active region including an upper channel pattern and an upper source/drain pattern connected to the upper channel pattern, a gate electrode provided on the lower and upper channel patterns and extended in a first direction, a lower interconnection layer including a first lower insulating layer, a second lower insulating layer, and a third lower insulating layer, which are sequentially stacked on the bottom surface of the substrate, a bit line in the third lower insulating layer, a first lower contact extending at least partially into the first lower insulating layer and the substrate, a second lower contact extending at least partially into the first and second lower insulating layers, the substrate, and the lower source/drain pattern, a magnetic tunnel junction pattern in the second lower insulating layer and connected to the first lower contact, and a spin-orbit torque line in the third lower insulating layer and connected to the second lower contact and the magnetic tunnel junction pattern. The magnetic tunnel junction pattern and the spin-orbit torque line may be between the bottom surface of the substrate and the bit line.

### BRIEF DESCRIPTION OF THE DRAWINGS

Embodiments will be more clearly understood from the following detailed description taken in conjunction with the accompanying drawings, wherein like reference numerals (when used) indicate corresponding elements throughout the several views, and in which:

FIG. 1A is a circuit diagram illustrating a cell array of a magnetic memory device according to an embodiment of the inventive concept;

FIG. 1B is a circuit diagram schematically illustrating a memory cell of a magnetic memory device according to an embodiment of the inventive concept;

FIGS. 2A and 2B are cross-sectional views exemplarily illustrating a magnetic tunnel junction pattern constituting the memory cell of FIG. 1B;

FIG. 3 is a plan view illustrating a magnetic memory device according to an embodiment of the inventive concept;

FIGS. 4A to 4E are cross-sectional views taken along lines A-A′, B-B′, C-C′, D-D′, and E-E′ of FIG. 3, respectively;

FIGS. 5A to 19B are cross-sectional views illustrating intermediate processes in an example method of fabricating a magnetic memory device according to an embodiment of the inventive concept;

FIG. 20A is a schematic circuit diagram illustrating a cell array of a magnetic memory device according to an embodiment of the inventive concept;

FIG. 20B is a plan view illustrating a magnetic memory device according to an embodiment of the inventive concept;

FIGS. 21A and 21B are cross-sectional views taken along lines C-C′ and B-B′ of FIG. 20B, respectively;

FIG. 22 is a plan view illustrating a magnetic memory device according to an embodiment of the inventive concept;

FIGS. 23A and 23B are cross-sectional views taken along lines A-A′ and B-B′ of FIG. 22, respectively;

FIG. 24A is a plan view illustrating a magnetic memory device according to an embodiment of the inventive concept;

FIG. 24B is a plan view illustrating a spin-orbit torque line of the magnetic memory device shown in FIG. 24A;

FIGS. 25A and 25B are cross-sectional views taken along lines A-A′ and B-B′ of FIG. 24A, respectively;

FIG. 26 is a plan view illustrating a magnetic memory device according to an embodiment of the inventive concept;

FIGS. 27A and 27B are cross-sectional views taken along lines A-A′ and B-B′ of FIG. 26, respectively;

FIG. 28A is a circuit diagram schematically illustrating a memory cell of a magnetic memory device according to an embodiment of the inventive concept;

FIG. 28B is a plan view illustrating the magnetic memory device of FIG. 28A; and

FIGS. 29A and 29B are cross-sectional views taken along lines A-A′ and B-B′ of FIG. 28B, respectively.

### DETAILED DESCRIPTION

Example embodiments of the inventive concepts will now be described more fully with reference to the accompanying drawings, in which example embodiments are shown.

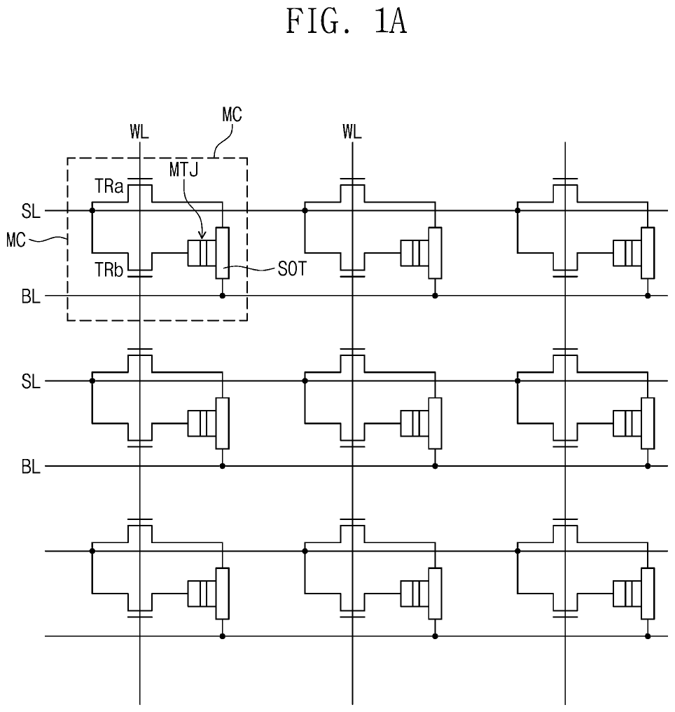

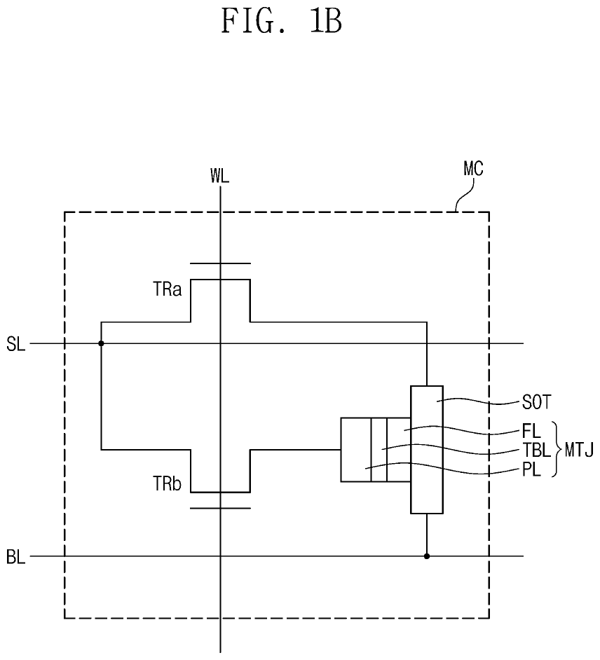

FIG. 1A is a schematic circuit diagram illustrating at least a portion of an example cell array of a magnetic memory device according to an embodiment of the inventive concept. FIG. 1B is a circuit diagram schematically illustrating a memory cell of a magnetic memory device according to an embodiment of the inventive concept.

Referring to FIGS. 1A and 1B, the cell array may include a plurality of word lines WL, a plurality of bit lines BL, a plurality of source lines SL, and a plurality of memory cells MC. Each of the memory cells MC may be connected at an intersection of a corresponding word line WL and bit line BL.

Each of the memory cells MC may include a magnetic tunnel junction pattern MTJ, a spin-orbit torque line SOT, an upper transistor TRa, and a lower transistor TRb.

The magnetic tunnel junction pattern MTJ may include a pinned magnetic pattern PL, a free magnetic pattern FL, and a tunnel barrier pattern TBL therebetween. The free magnetic pattern FL may be disposed between the spin-orbit torque line SOT and the tunnel barrier pattern TBL, and the pinned magnetic pattern PL may be spaced apart from the free magnetic pattern FL with the tunnel barrier pattern TBL interposed therebetween. The free magnetic pattern FL may be in contact with a surface of the spin-orbit torque line SOT. The term “contact” (or “contacted,” “contacting,” or similar terms, such as “connected” or “connecting”), as may be used herein, is broadly intended to include an electrical and/or physical connection, and may include other intervening elements unless stated otherwise. When there is an in-plane current flowing through the spin-orbit torque line SOT, a spin-orbit torque, which is induced by a spin Hall effect or a Rashba effect, may be applied to the free magnetic pattern FL, and as a result, a magnetization direction of the free magnetic pattern FL may be switched.

The memory cells MC may be arranged to form a plurality of rows and a plurality of columns. The memory cells MC of each row may be connected in common to a pair of source and bit lines SL and BL. The memory cells MC of each column may be connected in common to one of the word lines WL.

The upper and lower transistors TRa and TRb in each memory cell MC may be connected in common to a corresponding one of the word lines WL. The spin-orbit torque lines SOT of the memory cells MC of each row may be connected in common to one of the bit lines BL.

In a writing operation on a selected memory cell, the upper and lower transistors TRa and TRb may be turned on and off, respectively, by a selected word line WL. Thus, a write current may flow through the spin-orbit torque line SOT. A current direction of the write current may be changed depending on voltages applied to a selected bit line BL and a corresponding source line SL.

The write current may be an in-plane current of applying a spin-orbit torque to the free magnetic pattern FL of the magnetic tunnel junction pattern MTJ. The write current may flow through a region, which is adjacent to an interface between the spin-orbit torque line SOT and the free magnetic pattern FL, in a direction parallel to the interface. In the case where there is the write current, a spin current, which is caused by the spin Hall effect and the Rashba effect, may flow in a direction perpendicular to the interface between the spin-orbit torque line SOT and the free magnetic pattern FL, and as a result, a spin-orbit torque may be applied to the magnetic tunnel junction pattern MTJ. Thus, the magnetization direction of the free magnetic pattern FL may be switched to be parallel or antiparallel to that of the pinned magnetic pattern PL.

In a reading operation on the selected memory cell, the lower and upper transistors TRb and TRa may be turned on and off, respectively, by a selected word line WL. Thus, a reading current may flow from a selected bit line BL to a corresponding source line SL. The reading current may flow through the magnetic tunnel junction pattern MTJ and the spin-orbit torque line SOT. The reading current may pass through the magnetic tunnel junction pattern MTJ in a direction perpendicular to an interface between the spin-orbit torque line SOT and the magnetic tunnel junction pattern MTJ.

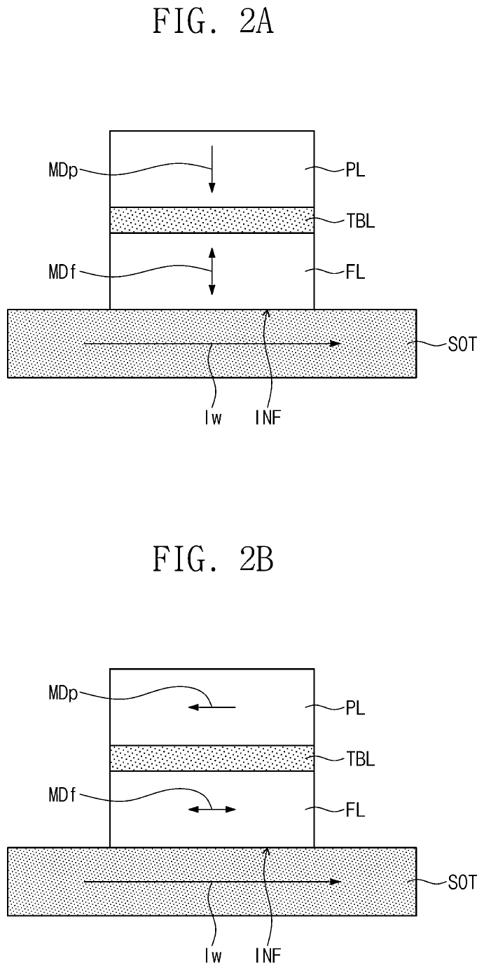

FIGS. 2A and 2B are cross-sectional views schematically illustrating a magnetic tunnel junction pattern constituting the memory cell of FIG. 1B.

Referring to FIGS. 2A and 2B, the magnetic tunnel junction pattern MTJ may include the free magnetic pattern FL, the tunnel barrier pattern TBL, and the pinned magnetic pattern PL, which are sequentially stacked on the spin-orbit torque line SOT in a direction perpendicular to an upper surface of the spin-orbit torque line SOT. The pinned magnetic pattern PL may have a magnetization direction MDp, which is fixed to a specific direction, and the free magnetic pattern FL may have a magnetization direction MDf that can be changed to be parallel or antiparallel to the magnetization direction MDp of the pinned magnetic pattern PL. As described with reference to FIGS. 1A and 1B, a write current Iw may flow through the spin-orbit torque line SOT and may flow through a region, which is adjacent to an interface INF between the spin-orbit torque line SOT and the free magnetic pattern FL, in a direction parallel to the interface INF. A spin-orbit torque, which is induced by the write current Iw, may be applied to the magnetic tunnel junction pattern MTJ, and thus, the magnetization direction of the free magnetic pattern FL may be switched to be parallel or antiparallel to the magnetization direction of the pinned magnetic pattern PL.

Referring to FIG. 2A, the magnetization directions MDf and MDp of the free and pinned magnetic patterns FL and PL, respectively, may be perpendicular to the interface INF between the spin-orbit torque line SOT and the free magnetic pattern FL. The free and pinned magnetic patterns FL and PL may exhibit a perpendicular magnetic anisotropy. In this case, each of the free and pinned magnetic patterns FL and PL may be formed of or include at least one of intrinsic perpendicular magnetic materials and extrinsic perpendicular magnetic materials. The intrinsic perpendicular magnetic material may include a material exhibiting a perpendicular magnetization property, even when there is no external cause (e.g., electromagnetic field). The intrinsic perpendicular magnetic material may include at least one of i) perpendicular magnetic materials (e.g., CoFeTb, CoFeGd, and CoFeDy), ii) perpendicular magnetic materials with L1₀ structure, iii) CoPt-based materials with hexagonal-close-packed structure, or iv) perpendicular magnetic structures. The perpendicular magnetic materials with the L1₀ structure may include at least one of L1₀ FePt, L1₀ FePd, L1₀ CoPd, or L1₀ CoPt. The perpendicular magnetic structures may include magnetic and non-magnetic layers that are alternatingly and repeatedly stacked. For example, the perpendicular magnetic structures may include at least one of (Co/Pt)ₙ, (CoFc/Pt)ₙ, (CoFc/Pd)ₙ, (Co/Pd)ₙ, (Co/Ni)ₙ, (CoNi/Pt)ₙ, (CoCr/Pt), or (CoCr/Pd)ₙ, where n is the number of pairs of the stacked layers. The extrinsic perpendicular magnetic material may include a material which exhibits an intrinsic in-plane magnetization property when there is no external cause but exhibits a perpendicular magnetization property by an external cause. For example, the extrinsic perpendicular magnetic material may have a perpendicular magnetization property, which is induced by a magnetic anisotropy that is caused when the free magnetic pattern FL (or the pinned magnetic pattern PL) is in contact with the tunnel barrier pattern TBL. The extrinsic perpendicular magnetic material may be formed of or include, for example, CoFeB.

Referring to FIG. 2B, the magnetization directions MDf and MDp of the free and pinned magnetic patterns FL and PL may be parallel to the interface INF between the spin-orbit torque line SOT and the free magnetic pattern FL. The free and pinned magnetic patterns FL and PL may exhibit an in-plane magnetic anisotropy. In this case, each of the free and pinned magnetic patterns FL and PL may be formed of or include a ferromagnetic material. The pinned magnetic pattern PL may further include an antiferromagnetic material fixing a magnetization direction of the ferromagnetic material in the pinned magnetic pattern PL.

In an embodiment, each of the free and pinned magnetic patterns FL and PL may include a Co-based Heusler alloy. The tunnel barrier pattern TBL may be formed of or include at least one of magnesium oxide, titanium oxide, aluminum oxide, magnesium-zinc oxide, or magnesium-boron oxide.

The spin-orbit torque line SOT may be formed of or include at least one of heavy metals or materials, which are doped with at least one of heavy metals. In an embodiment, the spin-orbit torque line SOT may include a material (M), which is doped with at least one of dopants (A) and (B). The dopant (A) may include yttrium (Y), zirconium (Zr), niobium (Nb), molybdenum (Mo), technetium (Tc), ruthenium (Ru), rhodium (Rh), palladium (Pd), cadmium (Cd), indium (In), antimony (Sb), tellurium (Te), hafnium (Hf), tantalum (Ta) (including high resistance amorphous β-Ta), tungsten (W), rhenium (Re), osmium (Os), iridium (Ir), platinum (Pt), gold (Au), mercury (Hg), thallium (Tl), lead (Pb), bismuth (Bi), polonium (Po), astatine (At), and/or combinations thereof. The dopant (B) may include at least one of vanadium (V), chromium (Cr), manganese (Mn), iron (Fc), cobalt (Co), nickel (Ni), phosphorus (P), sulfur(S), zinc (Zn), gallium (Ga), germanium (Ge), arsenic (As), selenium (Sc), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), antimony (Sb), tellurium (Te), iodine (I), lutetium (Lu), hafnium (Hf), tantalum (Ta), tungsten (W), rhenium (Re), osmium (Os), iridium (Ir), platinum (Pt), gold (Au), mercury (Hg), thallium (Tl), lead (Pb), bismuth (Bi), polonium (Po), astatine (At), lanthanum (La), cerium (Ce), prascodymium (Pr), neodymium (Nd), promethium (Pm), samarium (Sm), curopium (Eu), gadolinium (Gd), terbium (Tb), dysprosium (Dy), holmium (Ho), erbium (Er), thulium (Tm), and/or ytterbium (Yb). The material (M) may include at least one of aluminum (Al), titanium (Ti), vanadium (V), chromium (Cr), manganese (Mn), copper (Cu), zinc (Zn), silver (Ag), hafnium (Hf), tantalum (Ta), tungsten (W), rhenium (Rc), platinum (Pt) gold (Au), mercury (Hg), lead (Pb), silicon (Si), gallium (Ga), gallium manganese (GaMn), and/or gallium arsenic (GaAs).

The spin-orbit torque line SOT may include a chalcogen-based phase insulator (e.g., a topological insulator). The spin-orbit torque line SOT may be formed of or include a compound, which contains at least one of chalcogen elements (e.g., tellurium (Te) and selenium (Se)) and at least one of silicon (Si), germanium (Ge), bismuth (Bi), and antimony (Sb). In an embodiment, the spin-orbit torque line SOT may be formed of or include at least one of GeSe, BiSe, BiSbTe, GeTe, GeTeSe, GeSbTe, SiTe, or SiGeTe.

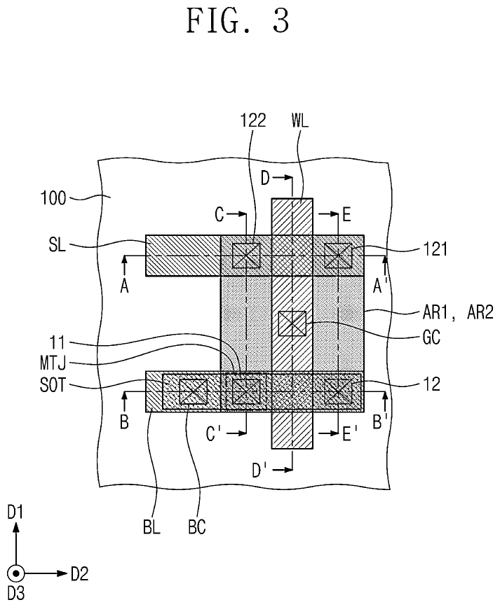

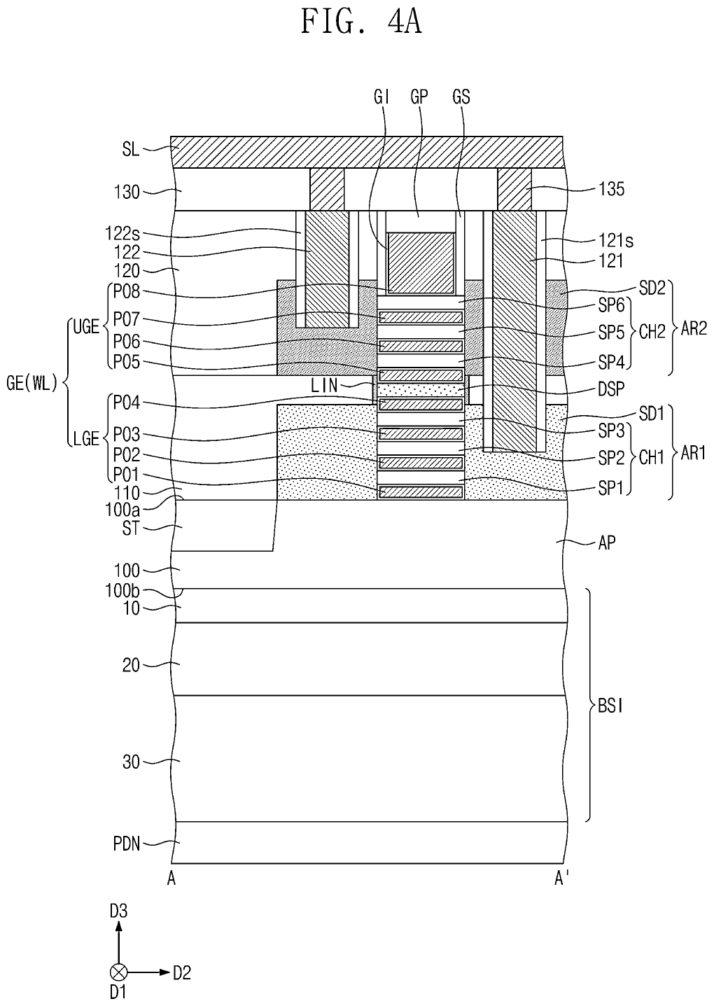

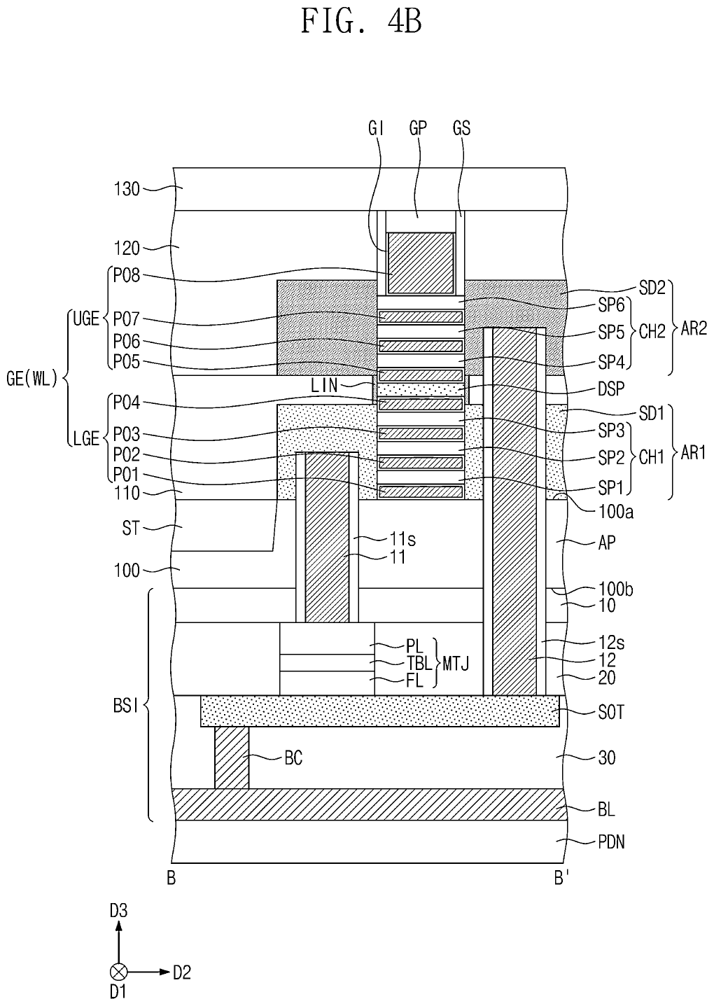

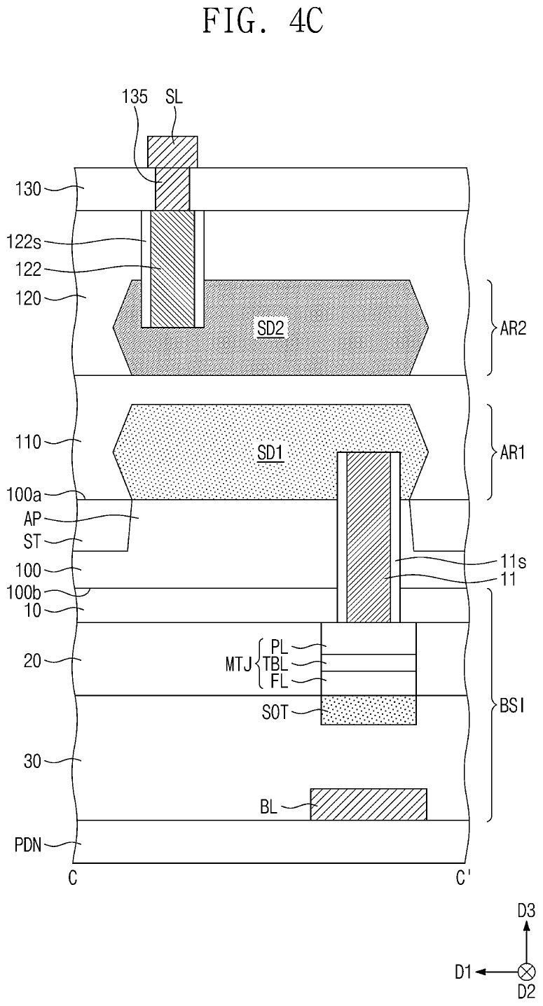

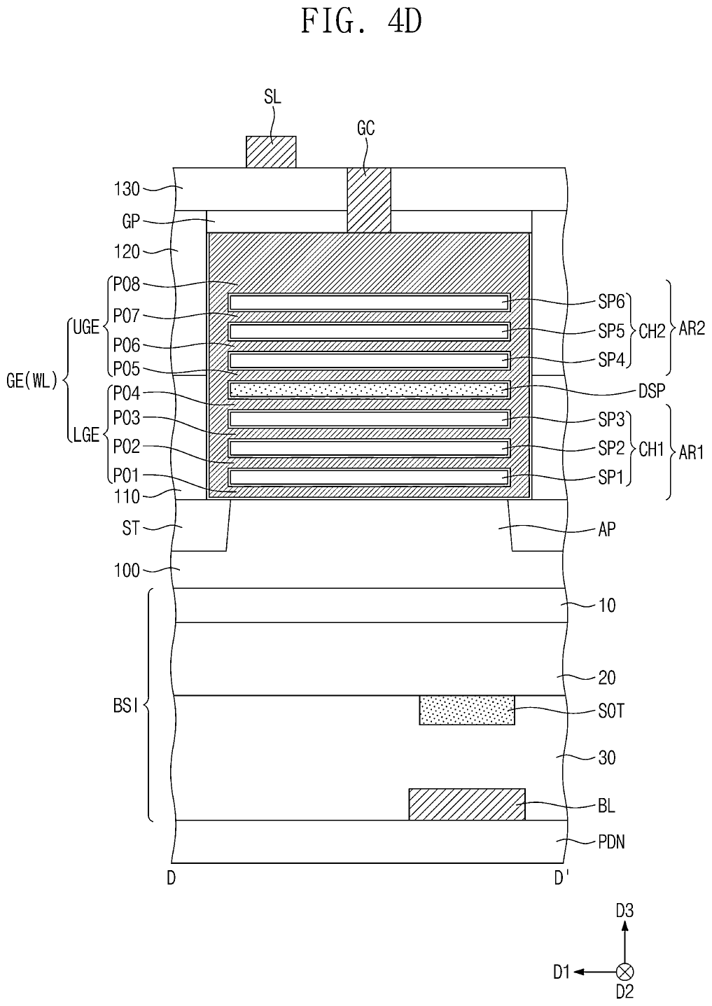

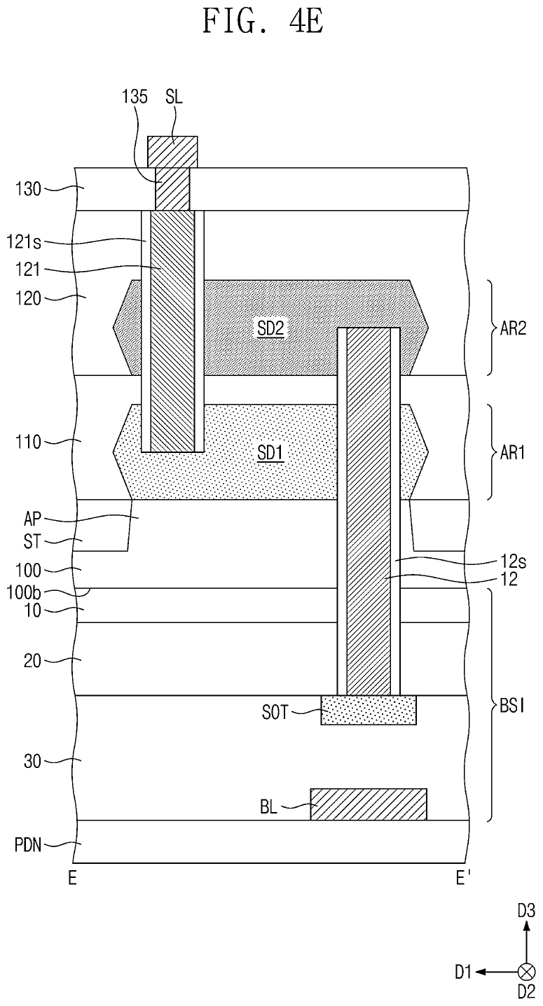

FIG. 3 is a plan view illustrating a magnetic memory device according to an embodiment of the inventive concept. FIGS. 4A to 4E are cross-sectional views taken along lines A-A′, B-B′, C-C′, D-D′, and E-E′ of FIG. 3, respectively.

Referring to FIGS. 3 and 4A to 4E, a substrate 100 having a top surface 100a and a bottom surface 100b, which are opposite to each other in a third direction D3, may be provided. In the present specification, a first direction D1 and a second direction D2 may be parallel to the top surface 100a of the substrate 100 and may not be parallel to each other. The third direction D3 may be perpendicular to the top surface 100a of the substrate 100. As an example, the first, second, and third directions D1, D2, and D3 may be orthogonal to each other. The substrate 100 may be a semiconductor substrate (e.g., a silicon substrate, a germanium substrate, and/or a silicon-germanium substrate).

A first active region AR1 and a second active region AR2 may be sequentially stacked on the substrate 100 in the third direction D3. One of the first and second active regions AR1 and AR2 may be a p-channel metal-oxide-semiconductor field-effect transistor (PMOSFET) region, and the other of the first and second active regions AR1 and AR2 may be an n-channel metal-oxide-semiconductor field-effect transistor (NMOSFET) region. The NMOS- and PMOS-FETs of the first and second active regions AR1 and AR2 may be vertically stacked to form a three-dimensional stack transistor.

An active pattern AP may be defined in an upper portion of the substrate 100 by a device isolation layer ST. The active pattern AP may be a vertically-protruding portion of the substrate 100. The first and second active regions AR1 and AR2 described above may be sequentially stacked on the active pattern AP. The device isolation layer ST may include a silicon oxide layer. A top surface of the device isolation layer ST may be coplanar with or lower than a top surface of the active pattern AP. The device isolation layer ST may not cover lower and upper channel patterns CH1 and CH2, which will be described below. The term “cover” (or “covered” or “covering,” or like terms), as may be used herein, is intended to broadly refer to a material, layer or structure being on or over another material, layer or structure, but does not require the material, layer or structure to entirely cover the other material, layer or structure, unless specifically stated otherwise.

The first active region AR1 may include a lower channel pattern CH1 and lower source/drain patterns SD1. The lower channel pattern CH1 may be interposed between the lower source/drain patterns SD1. The lower source/drain patterns SD1 may be disposed at both sides of the lower channel pattern CH1 and may be spaced apart from each other in the second direction D2. The lower channel pattern CH1 may be provided to connect the lower source/drain patterns SD1 to each other.

The lower channel pattern CH1 may include first to third semiconductor patterns SP1, SP2, and SP3, which are sequentially stacked. The first to third semiconductor patterns SP1, SP2, and SP3 may be spaced apart from each other in a vertical direction (i.e., the third direction D3). Each of the first to third semiconductor patterns SP1, SP2, and SP3 may be formed of or include silicon (Si), germanium (Ge), or silicon germanium (SiGe), although embodiments are not limited thereto. In an embodiment, each of the first to third semiconductor patterns SP1, SP2, and SP3 may be formed of or include crystalline silicon.

The lower source/drain patterns SD1 may be provided on the top surface of the active pattern AP. The lower source/drain patterns SD1 may be an epitaxial pattern formed by a selective epitaxial growth (SEG) process. In an embodiment, top surfaces of the lower source/drain patterns SD1 may be higher than a top surface of the third semiconductor pattern SP3 of the lower channel pattern CH1, relative to the upper surface 100a of the substrate 100 as a reference layer.

The lower source/drain patterns SD1 may be doped to have a first conductivity type. The first conductivity type may be an n-type or a p-type. The lower source/drain patterns SD1 may be formed of or include at least one of silicon germanium (SiGe), silicon (Si), and silicon carbide (SiC). The lower source/drain patterns SD1 may be configured to exert a tensile strain or a compressive strain on the lower channel pattern CH1.

A first interlayer insulating layer 110 may be provided on the lower source/drain patterns SD1. The first interlayer insulating layer 110 may cover the lower source/drain patterns SD1. A second interlayer insulating layer 120 and the second active region AR2 may be provided on the first interlayer insulating layer 110.

The second active region AR2 may include an upper channel pattern CH2 and upper source/drain patterns SD2. The upper channel pattern CH2 may be vertically overlapped with the lower channel pattern CH1. The term “overlapped” (or “overlapping,” or like terms), as used herein, is intended to broadly refer to a first element that intersects with at least a portion of a second element in the vertical direction (i.e., the third direction D3), but does not require that the first and second elements be completely aligned with one another in a horizontal plane (i.e., in the first direction D1 and/or the second direction D2). The upper source/drain pattern SD2 may be vertically overlapped with the lower source/drain pattern SD1. The upper channel pattern CH2 may be interposed between the upper source/drain patterns SD2. The upper source/drain patterns SD2 may be disposed at both sides of the upper channel pattern CH2 and may be spaced apart from each other in the second direction D2. The upper channel pattern CH2 may connect the upper source/drain patterns SD2 to each other.

The upper channel pattern CH2 may include fourth to sixth semiconductor patterns SP4, SP5, and SP6, which are sequentially stacked. The fourth to sixth semiconductor patterns SP4, SP5, and SP6 may be spaced apart from each other in the third direction D3. The fourth to sixth semiconductor patterns SP4, SP5, and SP6 of the upper channel pattern CH2 may be formed of or include the same semiconductor material as the first to third semiconductor patterns SP1, SP2, and SP3 of the lower channel pattern CH1 described above.

At least one dummy channel pattern DSP may be interposed between the lower channel pattern CH1 and the upper channel pattern CH2 in the third direction D3. The dummy channel pattern DSP may be spaced apart from the lower source/drain pattern SD1. The dummy channel pattern DSP may be spaced apart from the upper source/drain pattern SD2. In other words, the dummy channel pattern DSP may not be connected to any source/drain pattern. The dummy channel pattern DSP may be formed of or include a semiconductor material (e.g., silicon (Si), germanium (Ge), or silicon germanium (SiGe)) or a silicon-based insulating material (e.g., silicon oxide or silicon nitride), although embodiments are not limited thereto. In an embodiment, the dummy channel pattern DSP may be formed of or include the silicon-based insulating material.

The upper source/drain patterns SD2 may be provided on a top surface of the first interlayer insulating layer 110. Each of the upper source/drain patterns SD2 may be an epitaxial pattern formed by a selective epitaxial growth (SEG) process. In an embodiment, top surfaces of the upper source/drain patterns SD2 may be higher than a top surface of the sixth semiconductor pattern SP6 of the upper channel pattern CH2.

The upper source/drain patterns SD2 may be doped to have a second conductivity type. The second conductivity type may be different from the first conductivity type of the lower source/drain patterns SD1. The upper source/drain patterns SD2 may be formed of or include at least one of silicon germanium (SiGe), silicon (Si), or silicon carbide (SiC). The upper source/drain patterns SD2 may be configured to exert a tensile strain or a compressive strain on the upper channel pattern CH2.

The second interlayer insulating layer 120 may cover the upper source/drain patterns SD2. A top surface of the second interlayer insulating layer 120 may be coplanar with a top surface of each of first and second upper contacts 121 and 122, which will be described below, in the third direction D3, relative to the top surface 100a of the substrate 100.

A gate electrode GE may be disposed on the lower and upper channel patterns CH1 and CH2. The gate electrode GE may be used as the word line WL of FIG. 3. The gate electrode GE may be a bar-shaped pattern extended in the first direction D1, when viewed in a plan view. The gate electrode GE may be vertically overlapped with the stacked lower and upper channel patterns CH1 and CH2.

The gate electrode GE may be provided on top, bottom, and opposite side surfaces of each of the first to sixth semiconductor patterns SP1 to SP6. That is, the transistor according to the present embodiment may include a three-dimensional field effect transistor (e.g., multi-bridge channel field-effect transistor (MBCFET) or gate-all-around field-effect transistor (GAAFET)) in which the gate electrode GE is provided to three-dimensionally surround the channel pattern. The term “surround” (or “surrounding,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles.

The gate electrode GE may include a lower gate electrode LGE provided in the first active region AR1 and an upper gate electrode UGE provided in the second active region AR2. The lower and upper gate electrodes LGE and UGE may be vertically overlapped with each other. The lower gate electrode LGE and the upper gate electrode UGE may be connected to each other. In other words, the gate electrode GE according to the present embodiment may be a common gate electrode that is composed of the lower gate electrode LGE and the upper gate electrode UGE, which are provided on the lower channel pattern CH1 and the upper channel pattern CH2, respectively, and are connected to each other.

The lower gate electrode LGE may include a first portion PO1 interposed between the active pattern AP and the first semiconductor pattern SP1, a second portion PO2 interposed between the first semiconductor pattern SP1 and the second semiconductor pattern SP2, a third portion PO3 interposed between the second semiconductor pattern SP2 and the third semiconductor pattern SP3, and a fourth portion PO4 interposed between the third semiconductor pattern SP3 and the dummy channel pattern DSP.

The upper gate electrode UGE may include a fifth portion PO5 interposed between the dummy channel pattern DSP and the fourth semiconductor pattern SP4, a sixth portion PO6 interposed between the fourth semiconductor pattern SP4 and the fifth semiconductor pattern SP5, a seventh portion PO7 interposed between the fifth semiconductor pattern SP5 and the sixth semiconductor pattern SP6, and an eighth portion PO8 on the sixth semiconductor pattern SP6.

Gate spacers GS may be disposed on opposite side surfaces of the gate electrode GE, respectively. Referring to FIG. 4A, the gate spacers GS may be disposed on opposite side surfaces of the eighth portion PO8 of the upper gate electrode UGE, respectively. The gate spacers GS may be extended along the gate electrode GE or in the first direction D1. Top surfaces of the gate spacers GS may be higher than a top surface of the gate electrode GE in the third direction D3, relative to the top surface 100a of the substrate 100. The top surfaces of the gate spacers GS may be coplanar in the third direction D3 with the top surface of the second interlayer insulating layer 120. The gate spacers GS may be formed of or include at least one of SiCN, SiCON, or SiN. In an embodiment, the gate spacers GS may be a multi-layered structure, which includes at least two different materials selected from SiCN, SiCON, and SiN, although embodiments are not limited thereto. A pair of liner layers LIN may be provided on opposite side surfaces of each of the third and fourth portions PO3 and PO4 of the gate electrode GE, respectively.

A gate capping pattern GP may be provided on the top surface of the gate electrode GE. The gate capping pattern GP may be extended along the gate electrode GE or in the first direction D1. In an embodiment, the gate capping pattern GP may be formed of or include at least one of SION, SiCN, SiCON, or SiN.

A gate insulating layer GI may be interposed between the gate electrode GE and the first to sixth semiconductor patterns SP1 to SP6. The gate insulating layer GI may be formed of or include at least one of silicon oxide, silicon oxynitride, and/or high-k dielectric materials. In an embodiment, the gate insulating layer GI may include a silicon oxide layer, which is provided to directly cover a surface of each of the semiconductor patterns SP1 to SP6, and a high dielectric constant (high-k) dielectric layer, which is provided on the silicon oxide layer. In other words, the gate insulating layer GI may be a multi-layered structure including the silicon oxide layer and the high-k dielectric layer.

The high-k dielectric layer may be formed of or include at least one of high-k dielectric materials whose dielectric constants are higher than that of silicon oxide. The high-k dielectric material may include at least one of, for example, hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

The lower gate electrode LGE, which is provided in the first active region AR1, and the lower source/drain patterns SD1 may constitute the lower transistor TRb of FIGS. 1A and 1B. The upper gate electrode UGE, which is provided in the second active region AR2, and the upper source/drain patterns SD2 may constitute the upper transistor TRa of FIGS. 1A and 1B.

A third interlayer insulating layer 130 may be disposed on the second interlayer insulating layer 120. The third interlayer insulating layer 130 may cover the gate spacers GS and the gate capping pattern GP.

A gate contact GC may be provided to penetrate (i.e., extend at least partially into) the third interlayer insulating layer 130 and the gate capping pattern GP and may be electrically connected to the gate electrode GE. The gate contact GC may be formed of or include at least one of metallic materials selected from the group consisting of copper (Cu), aluminum (Al), ruthenium (Ru), cobalt (Co), tungsten (W), and molybdenum (Mo).

The source line SL may be disposed on the third interlayer insulating layer 130. When viewed in a plan view, the source line SL may be extended in the second direction D2. The source line SL may not be vertically overlapped with the gate contact GC.

The first and second upper contacts 121 and 122 may be electrically connected to the lower and upper source/drain patterns SD1 and SD2, respectively. Referring to FIG. 3, the first upper contact 121 and the second upper contact 122 may be disposed at both sides of the gate electrode GE. The first upper contact 121 and the second upper contact 122 may be spaced apart from each other in the second direction D2. When viewed in a plan view, the first and second upper contacts 121 and 122 may be vertically overlapped with the source line SL. In an embodiment, the first and second upper contacts 121 and 122 may be formed of or include a doped semiconductor material and/or a metallic material. For example, the metallic material may be selected from the group consisting of copper (Cu), aluminum (Al), ruthenium (Ru), cobalt (Co), tungsten (W), and molybdenum (Mo).

The first upper contact 121 may be extended from the top surface of the second interlayer insulating layer 120 to penetrate the second interlayer insulating layer 120, the upper source/drain patterns SD2, and a portion of the first interlayer insulating layer 110 and may be connected to the lower source/drain patterns SD1. A bottom surface of the first upper contact 121 may be in the lower source/drain pattern SD1.

A first upper separation structure 121s may enclose (i.e., extend around) the first upper contact 121. The first upper separation structure 121s may be interposed between the first upper contact 121 and the upper source/drain patterns SD2 and may be extended in the third direction D3. In other words, the first upper separation structure 121s may be interposed between the first upper contact 121 and the second interlayer insulating layer 120, between the first upper contact 121 and the upper source/drain patterns SD2, and between the first upper contact 121 and the first interlayer insulating layer 110. The first upper separation structure 121s may be extended into a region between the lower source/drain patterns SD1 and the first upper contact 121. The first upper separation structure 121s may be provided to expose a bottom surface of the first upper contact 121. The term “expose” (or “exposed,” or like terms) may be used to describe relationships between elements and/or with reference to intermediate processes in fabricating a semiconductor device, but may not require exposure of a particular element in the completed device. Likewise, the term “not exposed” may be used to describe relationships between elements and/or with reference to intermediate processes in fabricating a semiconductor device, but may not require a particular element to be unexposed in the completed device. Owing to the first upper separation structure 121s, the first upper contact 121 may be separated from the upper source/drain patterns SD2 and may be electrically disconnected or isolated from the upper source/drain patterns SD2. That is, the first upper contact 121 may be electrically and selectively connected to the lower source/drain pattern SD1.

The second upper contact 122 may be extended from the top surface of the second interlayer insulating layer 120 to penetrate a portion of the second interlayer insulating layer 120 and may be connected to the upper source/drain patterns SD2. A bottom surface of the second upper contact 122 may be in the upper source/drain pattern SD2.

A second upper separation structure 122s may extend around the second upper contact 122. However, in an embodiment, the second upper separation structure 122s may not be provided, unlike the illustrated structure. The second upper contact 122 may be electrically and selectively connected to the upper source/drain pattern SD2.

The first and second upper separation structures 121s and 122s may be formed of or include a silicon-based insulating material (e.g., silicon oxide or silicon nitride).

Source contacts 135 may be disposed in the third interlayer insulating layer 130. The source contacts 135 may electrically connect the source line SL to the first and second upper contacts 121 and 122, respectively.

A lower interconnection layer BSI may be disposed on the bottom surface 100b of the substrate 100. The lower interconnection layer BSI may include a first lower insulating layer 10, a second lower insulating layer 20, and a third lower insulating layer 30, which are sequentially stacked on the bottom surface 100b of the substrate 100 in the third direction D3. The bit line BL may be disposed in the third lower insulating layer 30. The bit line BL may be extended in the second direction D2. When viewed in a plan view, the bit line BL may be spaced apart from the source line SL in the first direction D1. A power delivery network layer PDN or an additional interconnection layer may be disposed on the lower interconnection layer BSI.

First and second lower contacts 11 and 12, which are electrically connected to the lower and upper source/drain patterns SD1 and SD2, respectively, may be provided. Referring to FIG. 3, the first lower contact 11 and the second lower contact 12 may be disposed at both sides of the gate electrode GE. The first lower contact 11 and the second lower contact 12 may be spaced apart from each other in the second direction D2. When viewed in a plan view, the first and second lower contacts 11 and 12 may be at least partially vertically overlapped with the bit line BL. In an embodiment, the first and second lower contacts 11 and 12 may include a doped semiconductor material and/or a metallic material. The metallic material may be selected from the group consisting of copper (Cu), aluminum (Al), ruthenium (Ru), cobalt (Co), tungsten (W), and molybdenum (Mo).

The first lower contact 11 may be provided to penetrate a portion of the lower interconnection layer BSI and may be connected to the lower source/drain patterns SD1. In detail, the first lower contact 11 may be extended from a bottom surface of the first lower insulating layer 10 to penetrate the first lower insulating layer 10 and the substrate 100 and may be connected to the lower source/drain patterns SD1. A top surface of the first lower contact 11 may be in the lower source/drain pattern SD1. A first lower separation structure 11s may be disposed to extend around the first lower contact 11. However, in an embodiment, the first lower separation structure 11s may be omitted, unlike the illustrated structure. The first lower contact 11 may be electrically and selectively connected to the lower source/drain pattern SD1.

The second lower contact 12 may be provided to penetrate a portion of the lower interconnection layer BSI and may be connected to the upper source/drain patterns SD2. In detail, the second lower contact 12 may be extended from a bottom surface of the second lower insulating layer 20 to penetrate the second lower insulating layer 20, the first lower insulating layer 10, the substrate 100, the lower source/drain patterns SD1, and the first interlayer insulating layer 110 and may be connected to the upper source/drain pattern SD2. A top surface of the second lower contact 12 may be in the upper source/drain pattern SD2. A second lower separation structure 12s may be disposed to extend around the second lower contact 12. The second lower separation structure 12s may be interposed between the second lower contact 12 and the lower source/drain patterns SD1 and may be extended in the third direction D3. In other words, the second lower separation structure 12s may be interposed between the second lower contact 12 and the first interlayer insulating layer 110, the lower source/drain patterns SD1, the substrate 100, the first lower insulating layer 10, and the second lower insulating layer 20. The second lower separation structure 12s may be extended into a region between the upper source/drain patterns SD2 and the second lower contact 12. The second lower separation structure 12s may be provided to expose the top surface of the second lower contact 12. Owing to the second lower separation structure 12s, the second lower contact 12 may be separated from the lower source/drain patterns SD1 and may be electrically disconnected or isolated from the lower source/drain patterns SD1. That is, the second lower contact 12 may be electrically and selectively connected to the upper source/drain pattern SD2.

Each of the first and second lower separation structures 11s and 12s may be formed of or include a silicon-based insulating material (e.g., silicon oxide or silicon nitride).

The magnetic tunnel junction pattern MTJ may be in the lower interconnection layer BSI. In detail, the magnetic tunnel junction pattern MTJ may be disposed in the second lower insulating layer 20. The magnetic tunnel junction pattern MTJ may be in contact with and connected to the first lower contact 11. When viewed in a plan view, the magnetic tunnel junction pattern MTJ may be at least partially vertically overlapped with the first lower contact 11. The magnetic tunnel junction pattern MTJ may include the free magnetic pattern FL, the pinned magnetic pattern PL, and the tunnel barrier pattern TBL therebetween. The pinned magnetic pattern PL may be disposed between the tunnel barrier pattern TBL and the first lower contact 11, and the free magnetic pattern FL may be spaced apart from the pinned magnetic pattern PL with the tunnel barrier pattern TBL interposed therebetween. The magnetic tunnel junction pattern MTJ may be configured to have substantially the same features as the magnetic tunnel junction pattern MTJ described with reference to FIGS. 2A and 2B. The magnetic tunnel junction pattern MTJ may be electrically connected to the lower source/drain pattern SD1 through the first lower contact 11. In other words, the magnetic tunnel junction pattern MTJ may be electrically connected to a source/drain terminal of the lower transistor described with reference to FIGS. 1A and 1B.

The spin-orbit torque line SOT may be disposed in the lower interconnection layer BSI. In detail, the spin-orbit torque line SOT may be on the second lower insulating layer 20. The spin-orbit torque line SOT may be a bar-shaped pattern that is extended in the second direction D2. The spin-orbit torque line SOT may be at least partially vertically overlapped with the bit line BL, when viewed in a plan view.

The spin-orbit torque line SOT may be in contact with and connected to the magnetic tunnel junction pattern MTJ and the second lower contact 12. The spin-orbit torque line SOT may be electrically connected to the upper source/drain pattern SD2 through the second lower contact 12.

The magnetic tunnel junction pattern MTJ and the spin-orbit torque line SOT may be between the bottom surface 100b of the substrate 100 and the bit line BL. That is, the bit line BL may be spaced apart from the bottom surface 100b of the substrate 100, with the magnetic tunnel junction pattern MTJ and the spin-orbit torque line SOT interposed therebetween.

A bit line contact BC may be disposed in the lower interconnection layer BSI. In detail, the bit line contact BC may be disposed in the third lower insulating layer 30. The bit line contact BC may electrically connect the spin-orbit torque line SOT to the bit line BL.

A spin-orbit torque magnetic memory device (e.g., an SOT-MRAM device) may have a high operation speed, compared with a spin transfer torque magnetic memory device (e.g., a STT-MRAM device), and since current paths in the read and write operations are different from each other, it may be possible to stably store data in the cell. However, for the SOT-MRAM device, in the case where the number of the terminals and the transistors increases, the area of the cell may be undesirably increased.

According to an embodiment of the inventive concept, an integration density of the magnetic memory device may be increased by using two transistors, which are vertically stacked, and by forming a contact from a rear surface of the substrate, it may be possible to reduce the complexity of the interconnection structure. That is, as described with reference to FIGS. 3 and 4A to 4E, by vertically stacking the lower and upper source/drain patterns SD1 and SD2, it may be possible to increase the integration density of the magnetic memory device. In addition, by forming the lower interconnection layer BSI on the bottom surface 100b of the substrate 100 and disposing the magnetic tunnel junction pattern MTJ and the spin-orbit torque line SOT in the lower interconnection layer BSI, it may be possible to reduce the complexity of the interconnection structure. In this case, it may be possible to easily increase an integration density of the SOT-MRAM device.

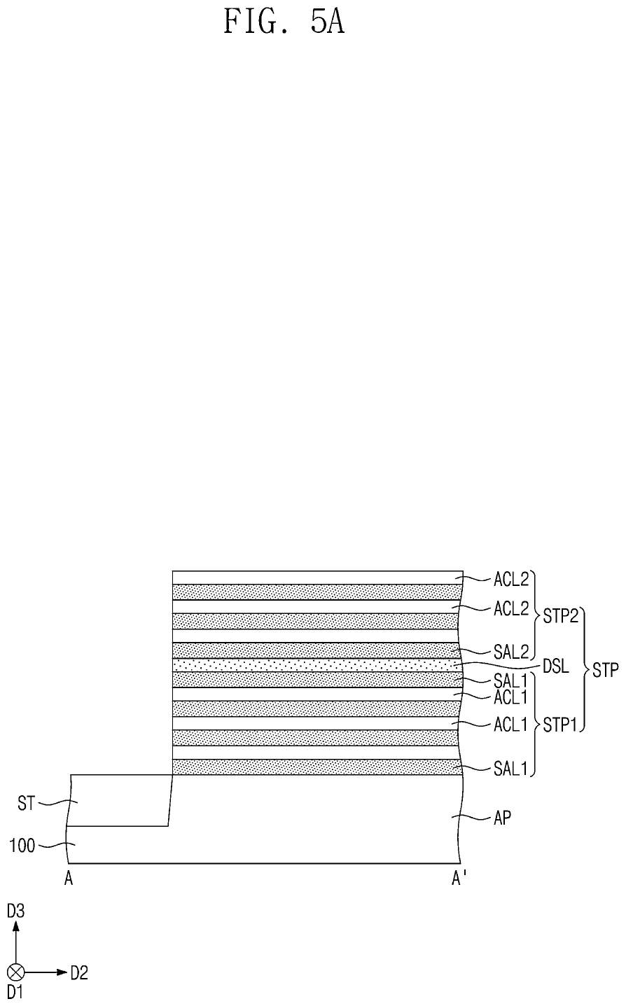

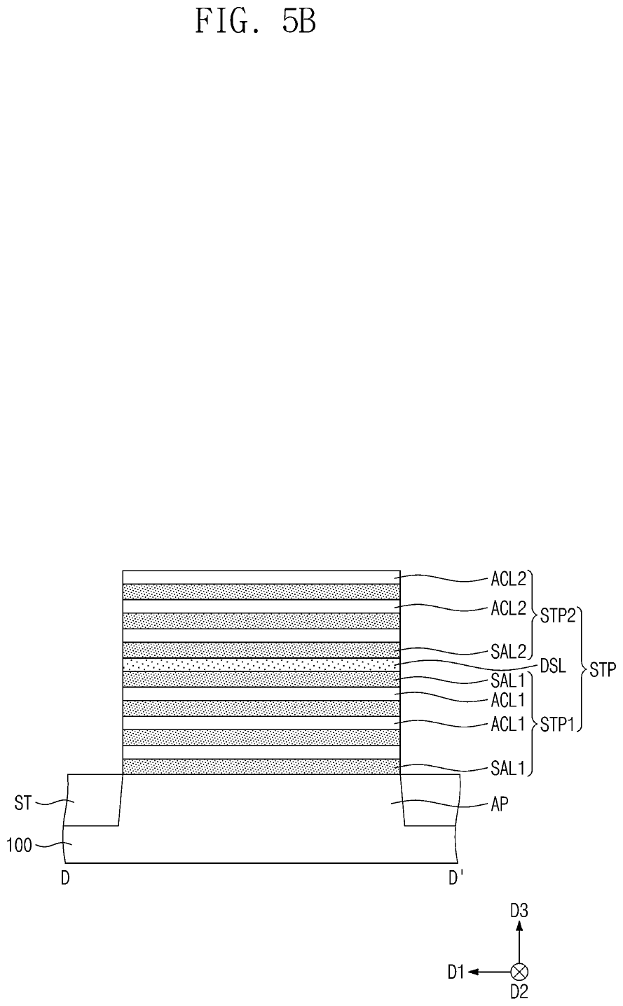

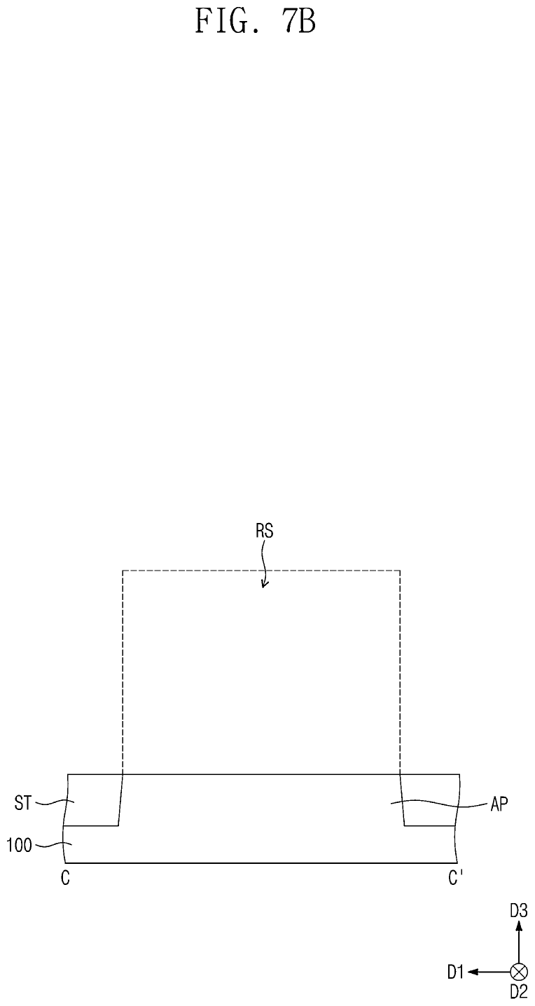

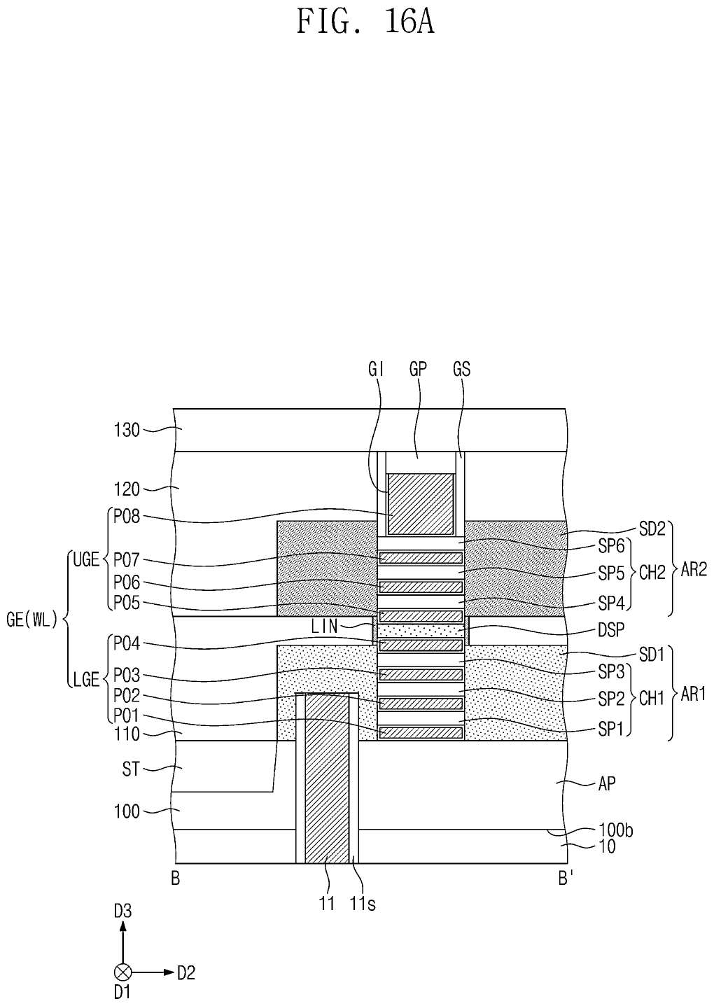

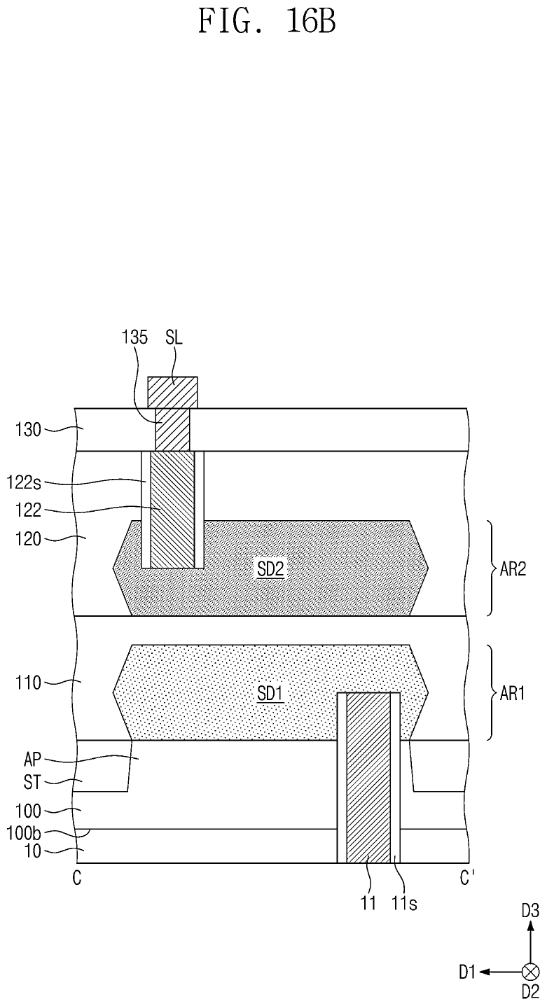

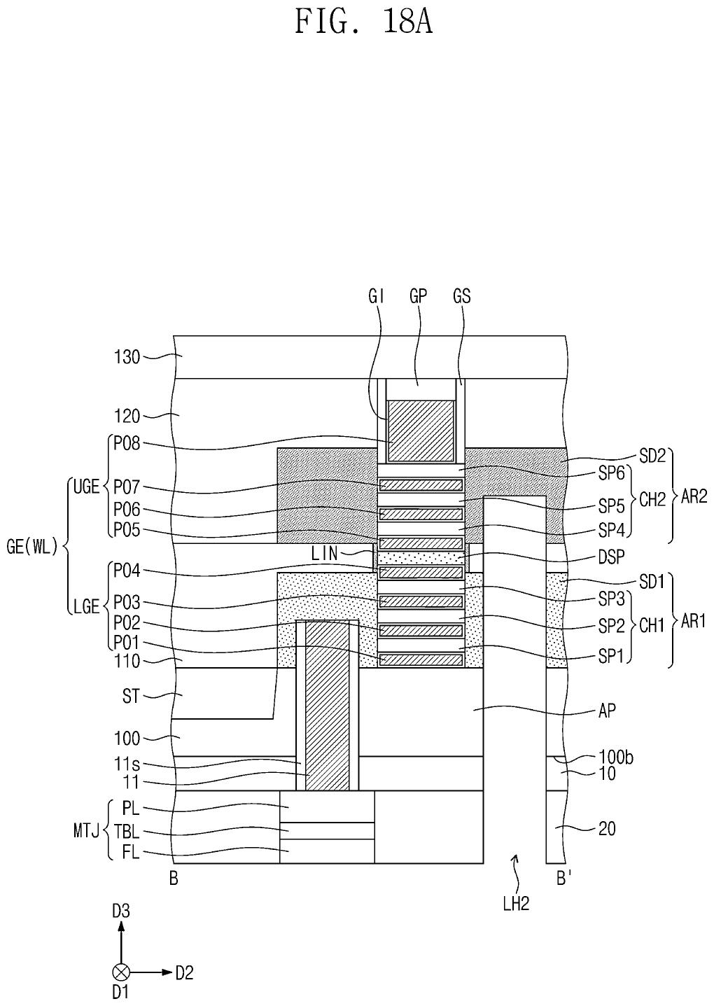

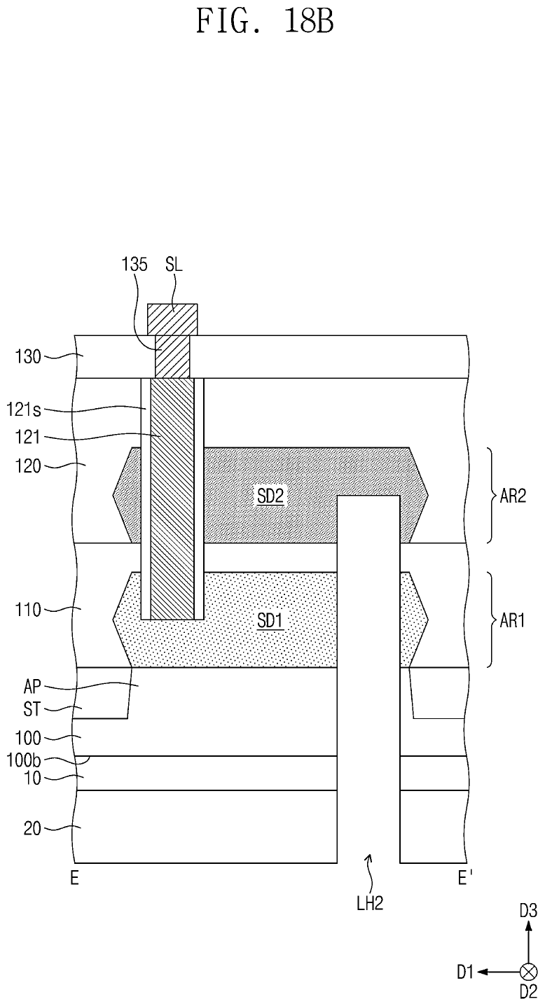

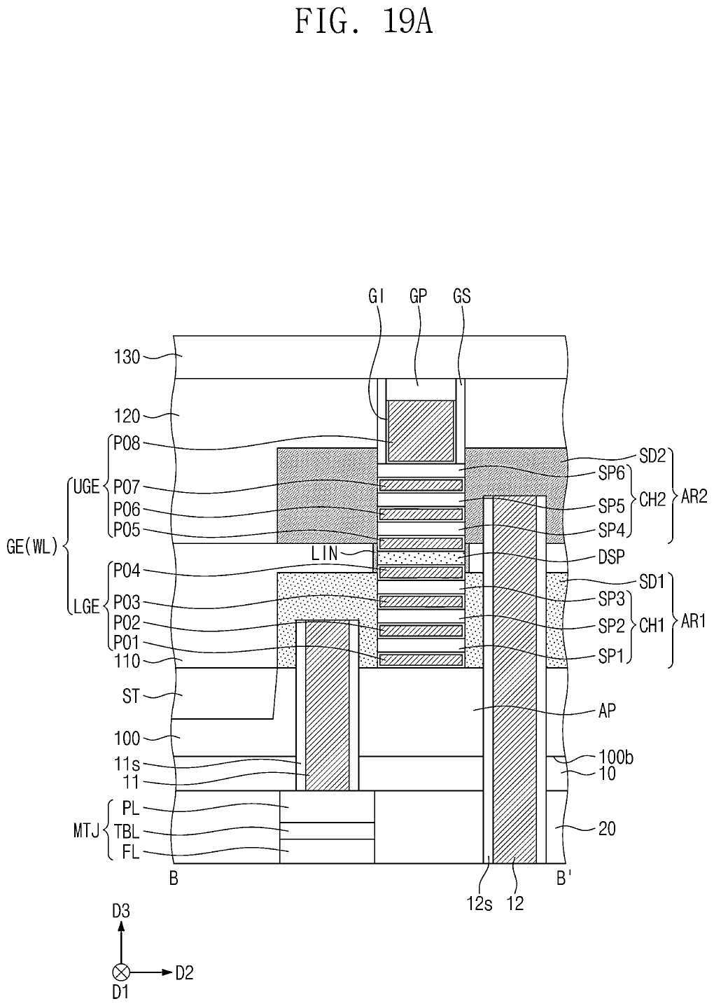

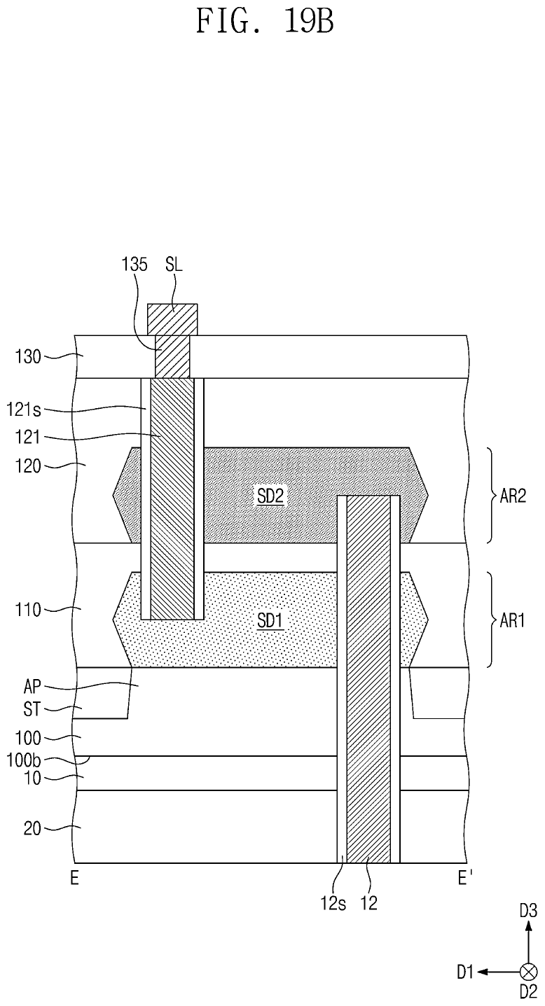

FIGS. 5A to 19B are cross-sectional views illustrating intermediate processes in an example method of fabricating a magnetic memory device according to an embodiment of the inventive concept. In detail, FIGS. 5A, 6A, 7A, 8A, 9A, 10A, 11A, 12A, 13A, and 14A are cross-sectional views taken along the line A-A′ of FIG. 3. FIGS. 16A, 17A, 18A, and 19A are cross-sectional views taken along the line B-B′ of FIG. 3. FIGS. 7B, 8B, 9B, 12B, 13B, 14B, 15B, 16B, and 17B are cross-sectional views taken along the line C-C′ of FIG. 3. FIGS. 5B, 6B, 10B, and 11B are cross-sectional views taken along the line D-D′ of FIG. 3. FIGS. 18B and 19B are cross-sectional views taken along the line E-E′ of FIG. 3.

Referring to FIGS. 5A and 5B, first sacrificial layers SAL1 and first active layers ACL1 may be alternatingly stacked on the substrate 100 in the third direction D3. The first sacrificial layers SAL1 and the first active layers ACL1 may be formed of or include at least one of silicon (Si), germanium (Ge), or silicon germanium (SiGe) and may be formed of different materials from each other. For example, the first sacrificial layers SAL1 may be formed of or include silicon germanium (SiGe), and the first active layers ACL1 may be formed of or include silicon (Si).

A separation layer DSL may be formed on the uppermost one of the first sacrificial layers SAL1. In an embodiment, a cross-sectional thickness (i.e., in the third direction D3) of the separation layer DSL may be substantially equal to a cross-sectional thickness of the first sacrificial layer SAL1.

Second sacrificial layers SAL2 and second active layers ACL2 may be alternatively stacked on the separation layer DSL in the third direction D3. Each of the second sacrificial layers SAL2 may be formed of or include the same material as the first sacrificial layer SAL1, and each of the second active layers ACL2 may be formed of or include the same material as the first active layer ACL1. The separation layer DSL may be interposed between the first sacrificial layer SAL1 and the second sacrificial layer SAL2.

A stacking pattern STP may be formed by patterning the first and second sacrificial layers SAL1 and SAL2, the first and second active layers ACL1 and ACL2, and the separation layer DSL which are stacked. The formation of the stacking pattern STP may include forming a hard mask pattern on the uppermost one of the second active layers ACL2 and sequentially etching the layers (e.g., SAL1, SAL2, ACL1, ACL2, and DSL), which are stacked on the substrate 100, using the hard mask pattern as an etch mask. During the formation of the stacking pattern STP, an upper portion of the substrate 100 may be patterned to form a trench defining the active pattern AP. The stacking pattern STP may be a bar-shaped pattern extended in the second direction D2.

The stacking pattern STP may include a lower stacking pattern STP1 on the active pattern AP, an upper stacking pattern STP2 on the lower stacking pattern STP1, and the separation layer DSL between the lower and upper stacking patterns STP1 and STP2. The lower stacking pattern STP1 may include the first sacrificial layers SAL1 and the first active layers ACL1, which are alternately stacked. The upper stacking pattern STP2 may include the second sacrificial layers SAL2 and the second active layers ACL2, which are alternately stacked.

The device isolation layer ST may be formed on the substrate 100 to fill the trench. The term “fill” (or “filling,” or “fills,” or like terms), as may be used herein, is intended to refer broadly to either completely filling a defined space (e.g., the trench) or partially filling the defined space; that is, the defined space need not be entirely filled but may, for example, be partially filled or have voids or other spaces throughout. In an embodiment, the formation of the device isolation layer ST may include forming an insulating layer (not shown) on the substrate 100 to cover the active pattern AP and the stacking pattern STP and recessing the insulating layer to expose the stacking pattern STP.

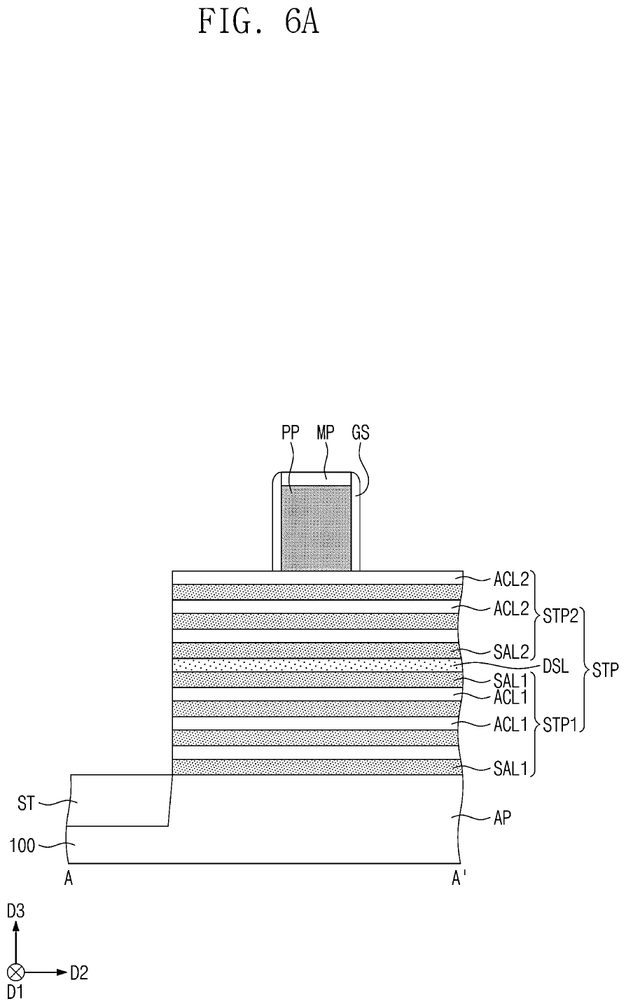

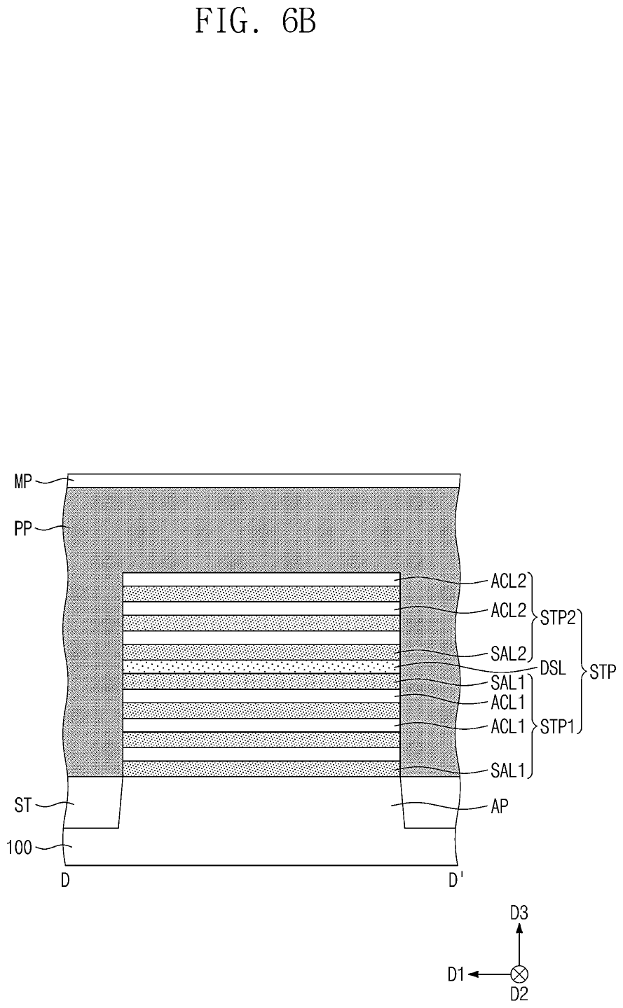

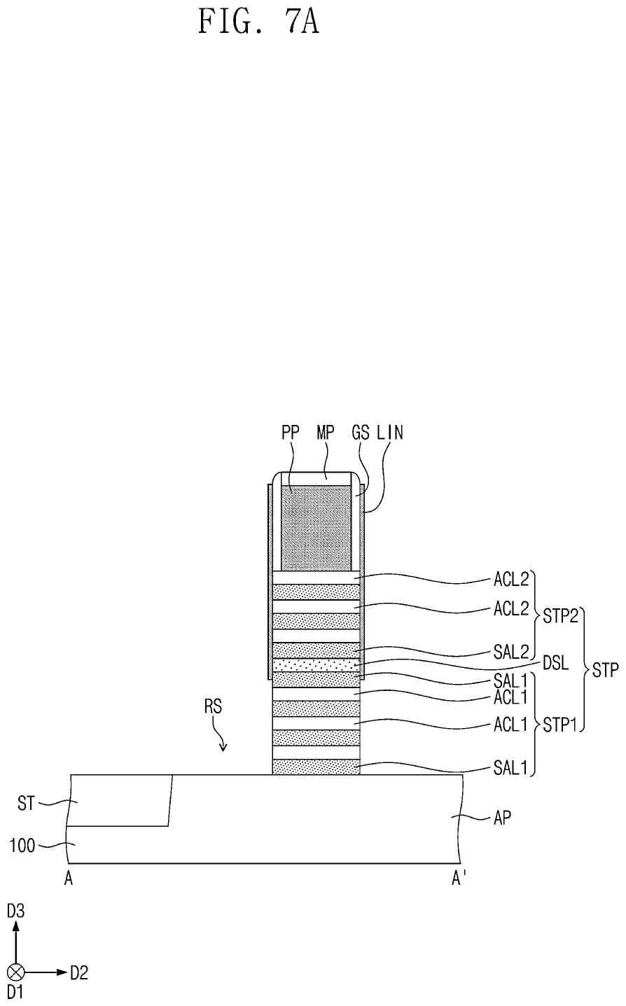

Referring to FIGS. 6A and 6B, a sacrificial pattern PP may be formed to cross the stacking pattern STP. The sacrificial pattern PP may be formed to have a line shape extending in the first direction D1. In an embodiment, the formation of the sacrificial pattern PP may include forming a sacrificial layer (not shown) on the substrate 100, forming a hard mask pattern MP on the sacrificial layer, and etching the sacrificial layer using the hard mask pattern MP as an etch mask. The sacrificial layer may be formed of or include amorphous silicon and/or polysilicon.

The gate spacers GS may be formed on opposite side surfaces of the sacrificial pattern PP, respectively. In an embodiment, the formation of the gate spacers GS may include conformally forming a spacer layer (not shown) on the substrate 100 and performing an anisotropic etching process on the spacer layer. The term “conformally” (or “conformal,” or like terms), as may be used herein in the context of a material layer or coating, is intended to refer broadly to a material layer or coating having a substantially uniform cross-sectional thickness relative to the contour of a surface to which the material layer is applied. The spacer layer may be formed of or include at least one of SiCN, SiCON, or SiN.

Referring to FIGS. 7A and 7B, recesses RS may be formed at opposite sides of the sacrificial pattern PP. In an embodiment, the recesses RS may be formed by performing an etching process on the stacking pattern STP using the gate spacers GS and the hard mask pattern MP as an etch mask.

The liner layers LIN may be formed on opposite side surfaces of the upper stacking pattern STP2, respectively. In some embodiments, the liner layers LIN may be formed on side surfaces of the separation layer DSL. The liner layers LIN may prevent the upper stacking pattern STP2 from being exposed to the recesses RS. The liner layers LIN may be formed to expose the lower stacking pattern STP1. In an embodiment, the liner layers LIN may be formed of or include silicon nitride.

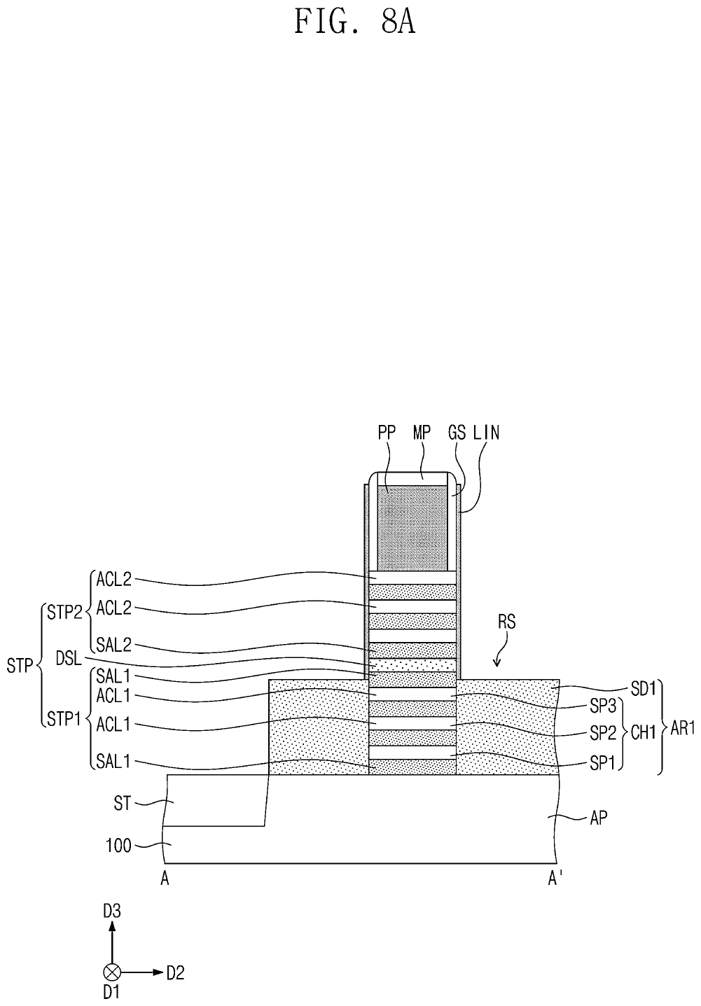

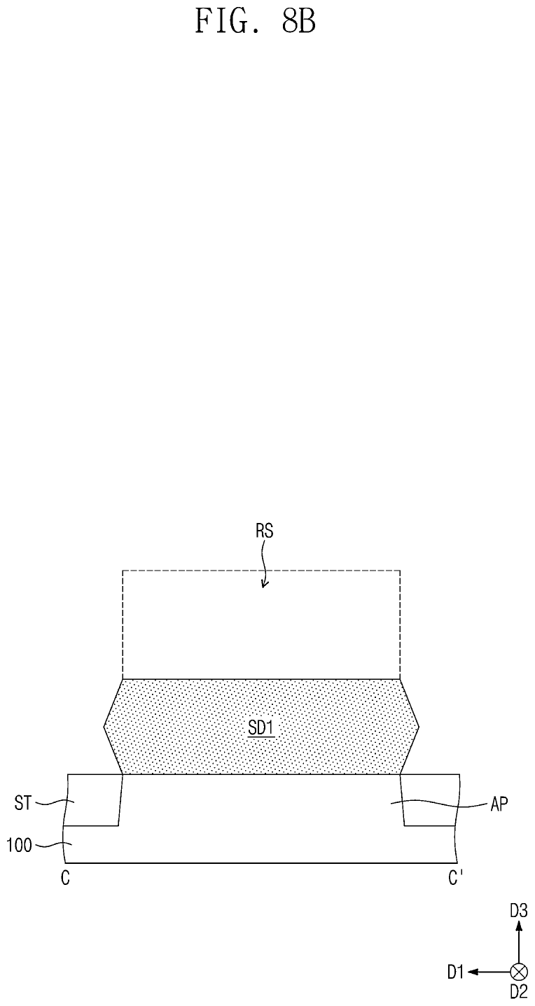

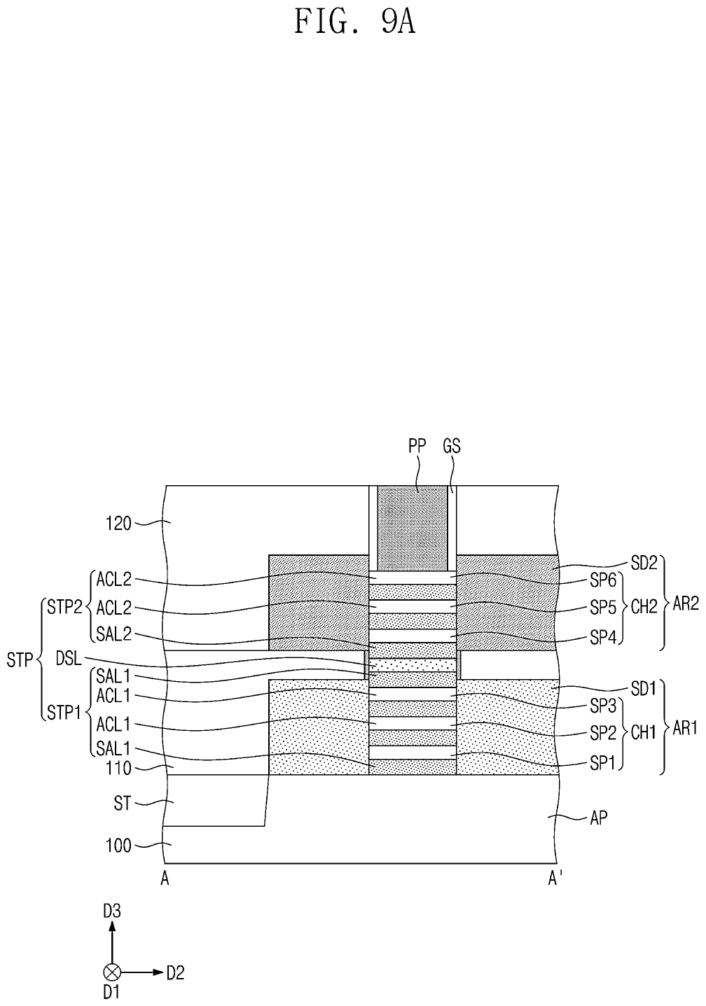

Referring to FIGS. 8A and 8B, the lower source/drain patterns SD1 may be formed in the recesses RS, respectively. In detail, the lower source/drain patterns SD1 may be formed by a first selective epitaxial growth (SEG) process using an exposed side surface of the lower stacking pattern STP1 as a seed layer. The lower source/drain patterns SD1 may be grown using the first active layers ACL1 and the active pattern AP, which are exposed by the recess RS, as a seed layer. In an embodiment, the first SEG process may include a chemical vapor deposition (CVD) process or a molecular beam epitaxy (MBE) process.

In an embodiment, during the first SEG process, impurities may be injected in-situ into the lower source/drain patterns SD1. In another embodiment, impurities may be injected into the lower source/drain patterns SD1, after the formation of the lower source/drain patterns SD1. The lower source/drain patterns SD1 may be doped to have a first conductivity type.

The first active layers ACL1, which are interposed between the lower source/drain patterns SD1, may constitute the lower channel pattern CH1. That is, the first to third semiconductor patterns SP1, SP2, and SP3 of the lower channel pattern CH1 may be formed from the first active layers ACL1. The lower channel pattern CH1 and the lower source/drain patterns SD1 may constitute the first active region AR1.

A side surface of the upper stacking pattern STP2 may be covered with the liner layer LIN. That is, owing to the liner layer LIN, the second active layers ACL2 of the upper stacking pattern STP2 may not be exposed to the outside during the first SEG process. Thus, during the first SEG process, an additional semiconductor layer may not be grown on the upper stacking pattern STP2.

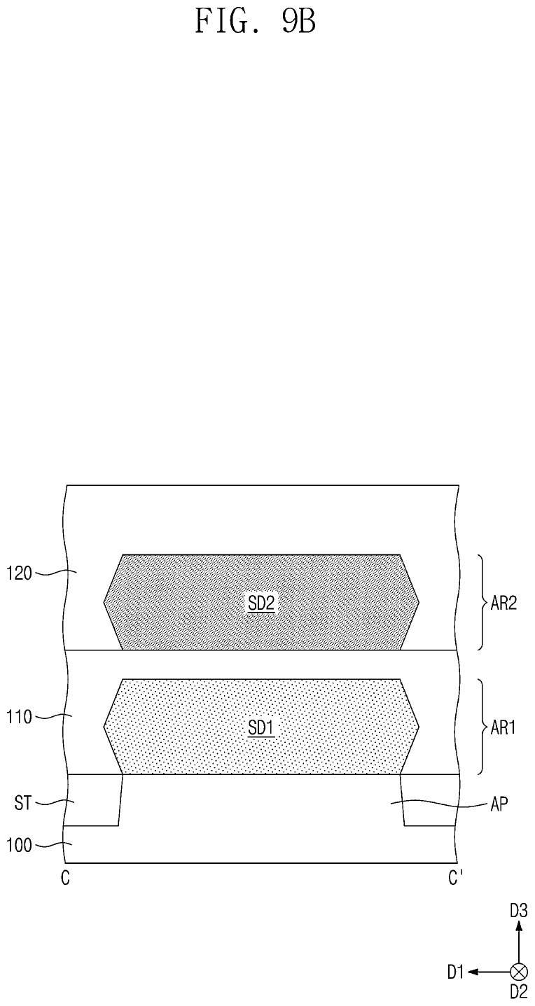

Referring to FIGS. 9A and 9B, the first interlayer insulating layer 110 may be formed to cover the lower source/drain patterns SD1. A top surface of the first interlayer insulating layer 110 may be recessed to a level lower than a bottom surface of the lowermost one of the second active layers ACL2 in the third direction D3, relative to the top surface of the substrate 100 as a reference layer.

A portion of the liner layer LIN, which is exposed by the recess RS, may be removed. A remaining portion of the liner layer LIN, which is covered with the first interlayer insulating layer 110, may cover a side surface of the separation layer DSL. Since the liner layer LIN is removed, the second active layers ACL2 may be exposed through the recess RS.

The upper source/drain patterns SD2 may be formed on opposite side surfaces of the upper stacking pattern STP2, respectively. In detail, the upper source/drain patterns SD2 may be formed by a second SEG process using the side surface of the upper stacking pattern STP2 as a seed layer. The upper source/drain patterns SD2 may be grown using the second active layers ACL2, which are exposed by the recess RS, as a seed layer. The upper source/drain patterns SD2 may be doped to have the second conductivity type different from the first conductivity type.

The second active layers ACL2, which are interposed between the upper source/drain patterns SD2, may constitute the upper channel pattern CH2. That is, the fourth to sixth semiconductor patterns SP4, SP5, and SP6, respectively, of the upper channel pattern CH2 may be formed from the second active layers ACL2. The upper channel pattern CH2 and the upper source/drain patterns SD2 may constitute the second active region AR2.

The second interlayer insulating layer 120 may be formed on the first interlayer insulating layer 110 to cover the hard mask pattern MP, the gate spacers GS, and the upper source/drain patterns SD2.

The second interlayer insulating layer 120 may be planarized to expose a top surface of the sacrificial pattern PP. The planarization of the second interlayer insulating layer 120 may be performed using an etch-back process or a chemical mechanical polishing (CMP) process. The hard mask pattern MP may be fully removed during the planarization process. As a result, the top surface of the second interlayer insulating layer 120 may be coplanar with the top surface of the sacrificial pattern PP and the top surfaces of the gate spacers GS.

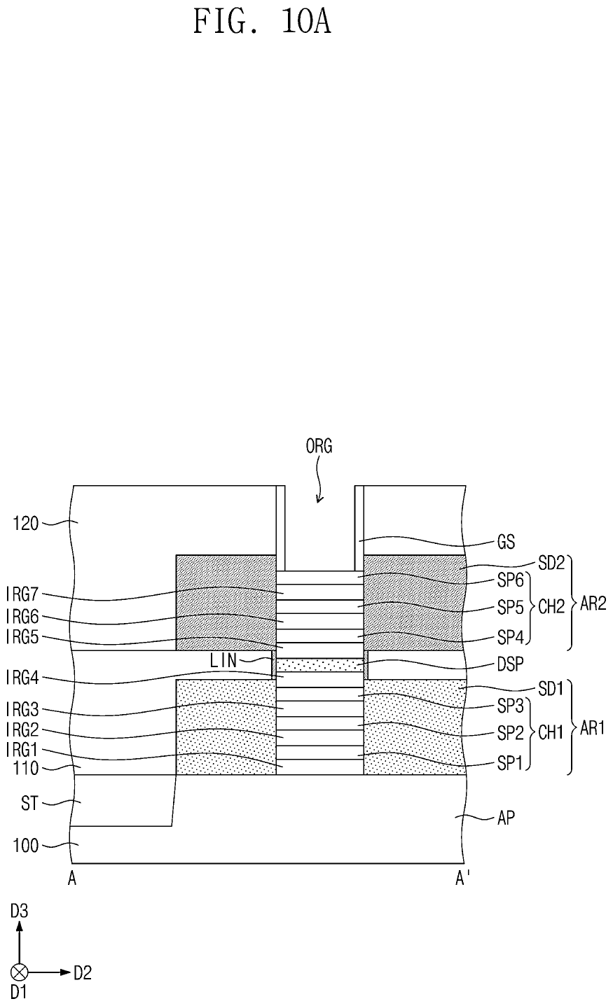

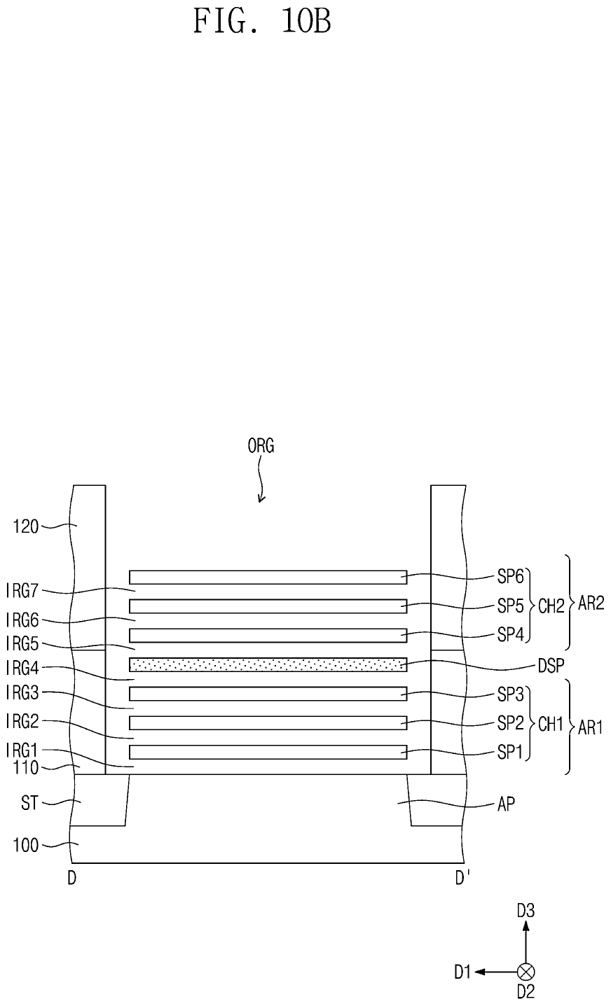

Referring to FIGS. 10A and 10B, the sacrificial pattern PP may be selectively removed. As a result of the removal of the sacrificial pattern PP, an outer region ORG (e.g., recess) may be formed to expose the lower and upper channel patterns CH1 and CH2. In an embodiment, the formation of the outer region ORG may be performed through a wet etching process using an etching solution capable of selectively etching the sacrificial pattern PP.

In an embodiment, the separation layer DSL, which is exposed through the outer region ORG, may be replaced with the dummy channel pattern DSP. In another embodiment, the separation layer DSL may be left as it is, thereby forming the dummy channel pattern DSP.

First to seventh inner regions IRG1 to IRG7 may be respectively formed by selectively removing the first and second sacrificial layers SAL1 and SAL2, which are exposed through the outer region ORG. In detail, an etching process may be performed to leave the first to sixth semiconductor patterns SP1 to SP6 and the dummy channel pattern DSP and to selectively remove only the first and second sacrificial layers SAL1 and SAL2.

Since the first and second sacrificial layers SAL1 and SAL2 are selectively removed, the first to third semiconductor patterns SP1, SP2, and SP3 may be left on the first active region AR1, and the fourth to sixth semiconductor patterns SP4, SP5, and SP6 may be left on the second active region AR2. The dummy channel pattern DSP may be left between the third semiconductor pattern SP3 and the fourth semiconductor pattern SP4.

An empty space between the active pattern AP and the first semiconductor pattern SP1 may be defined as the first inner region IRG1, an empty space between the first semiconductor pattern SP1 and the second semiconductor pattern SP2 may be defined as the second inner region IRG2, an empty space between the second semiconductor pattern SP2 and the third semiconductor pattern SP3 may be defined as the third inner region IRG3, an empty space between the third semiconductor pattern SP3 and the dummy channel pattern DSP may be defined as the fourth inner region IRG4, an empty space between the dummy channel pattern

DSP and the fourth semiconductor pattern SP4 may be defined as the fifth inner region IRG5, an empty space between the fourth semiconductor pattern SP4 and the fifth semiconductor pattern SP5 may be defined as the sixth inner region IRG6, and an empty space between the fifth semiconductor pattern SP5 and the sixth semiconductor pattern SP6 may be defined as the seventh inner region IRG7.

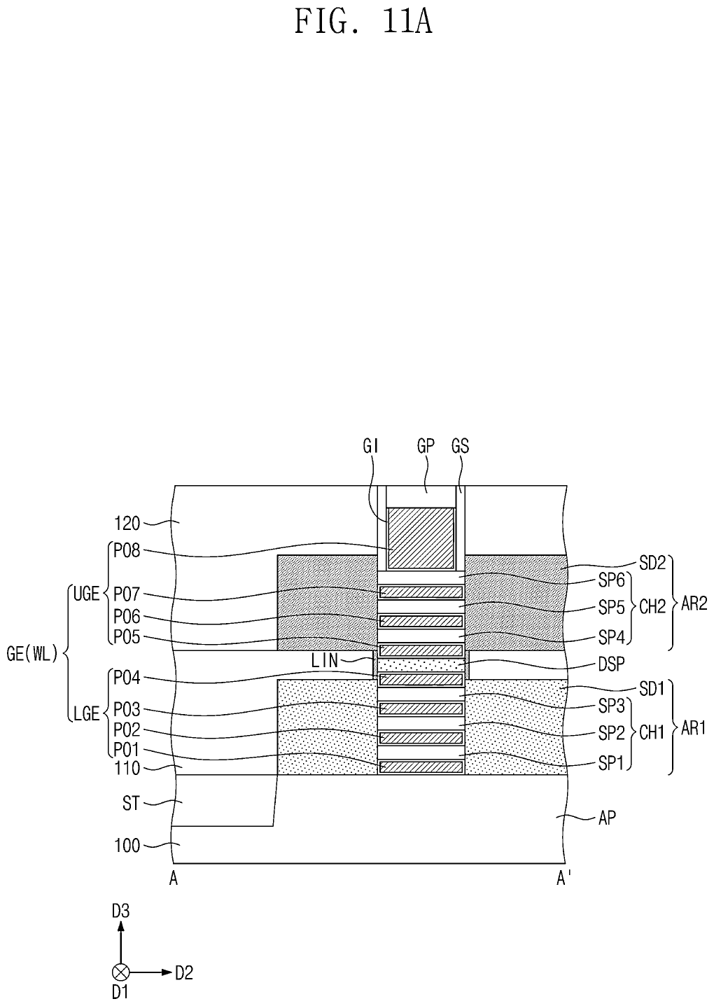

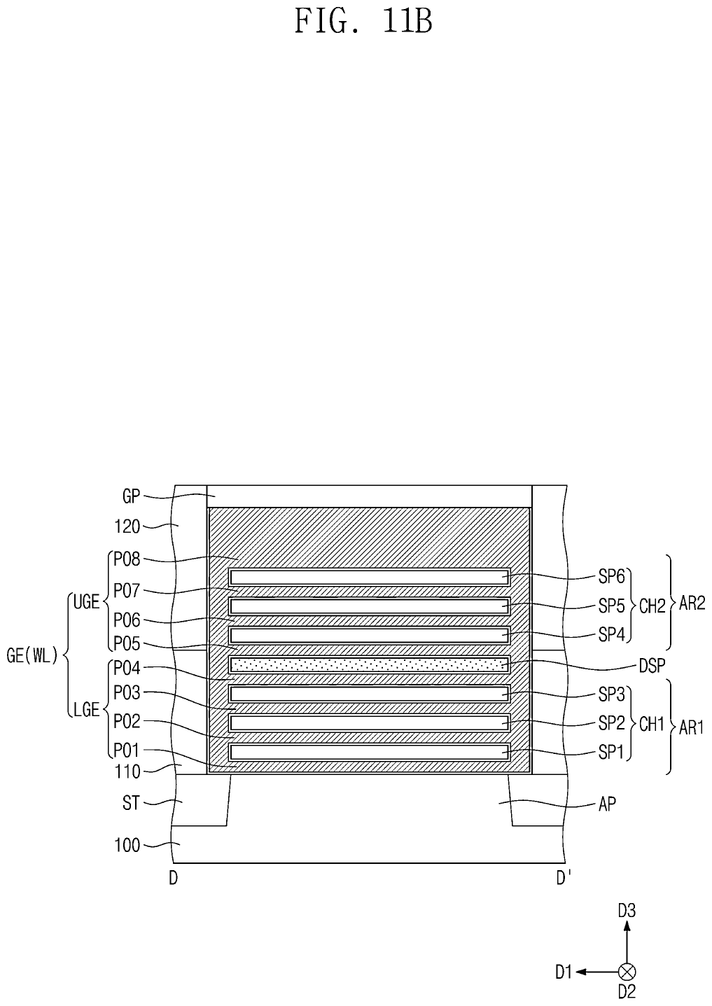

Referring to FIGS. 11A and 11B, the gate insulating layer GI may be conformally formed on exposed surfaces of the first to seventh semiconductor patterns SP1 to SP7. The gate electrode GE may be formed on the gate insulating layer GI. The formation of the gate electrode GE may include forming the first to seventh portions PO1 to PO7 in the first to seventh inner regions IRG1 to IRG7, respectively, and forming the eighth portion PO8 in the outer region ORG.

The gate electrode GE may be vertically recessed to have a reduced height. The gate capping pattern GP may be formed on the recessed gate electrode GE. A planarization process may be performed on the gate capping pattern GP such that a top surface of the gate capping pattern GP is coplanar with the top surface of the second interlayer insulating layer 120.

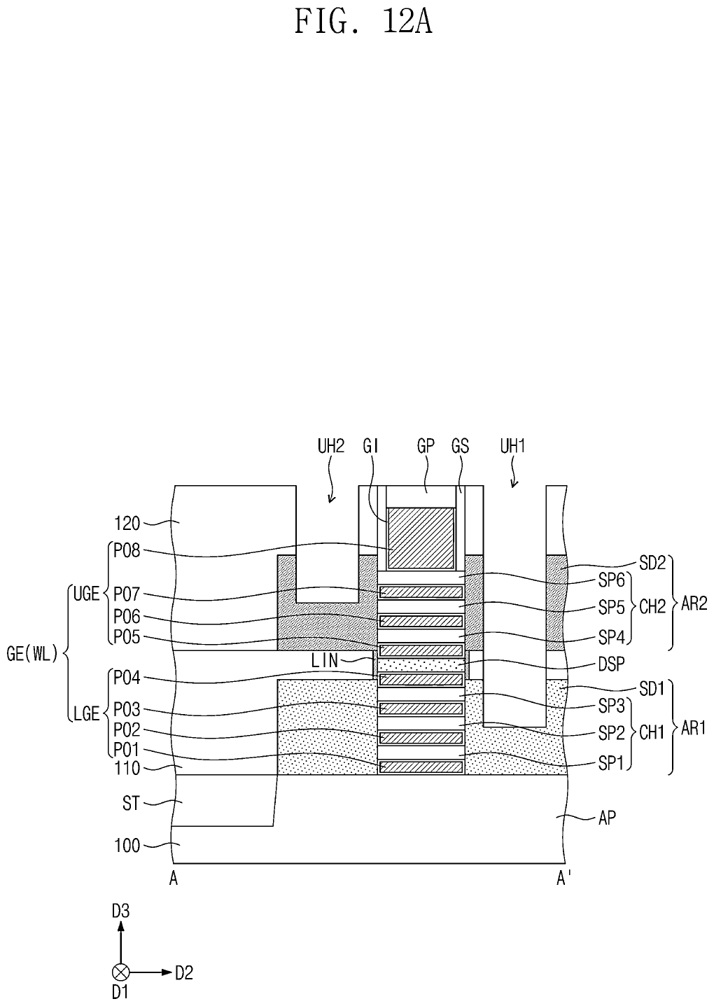

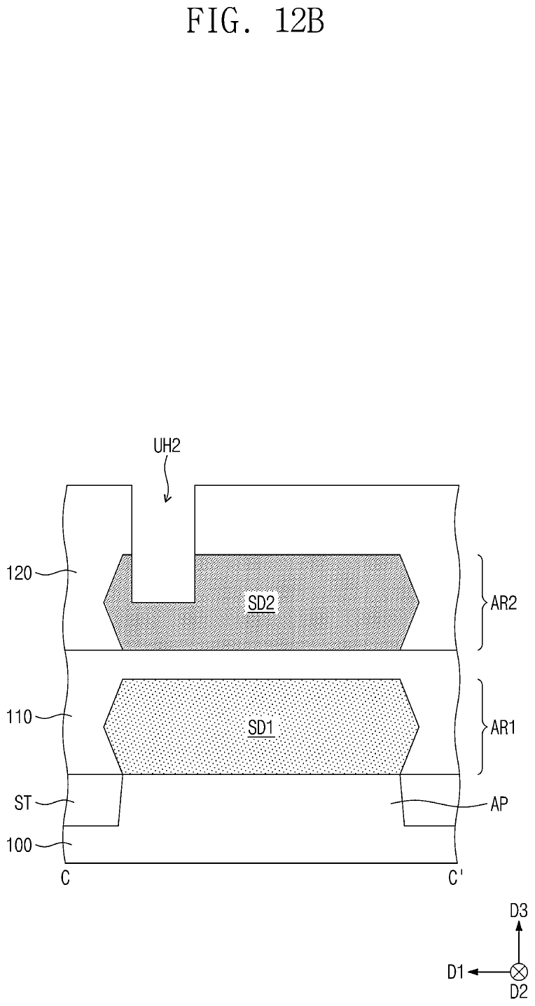

Referring to FIGS. 12A and 12B, a first upper hole (i.e., opening) UH1 and a second upper hole UH2 may be formed at opposite sides of the gate electrode GE. The first upper hole UH1 and the second upper hole UH2 may be spaced apart from each other in the second direction D2, with the gate electrode GE interposed therebetween.

The first upper hole UH1 may be extended in the third direction D3 from the top surface of the second interlayer insulating layer 120 to the lower source/drain patterns SD1. The first upper hole UH1 may be formed to penetrate (i.e., extend in) the second interlayer insulating layer 120, the upper source/drain pattern SD2, the first interlayer insulating layer 110, and a portion of the lower source/drain pattern SD1. A bottom surface of the first upper hole UH1 may be in the lower source/drain pattern SD1.

The second upper hole UH2 may be extended from the top surface of the second interlayer insulating layer 120 to the upper source/drain pattern SD2. The second upper hole UH2 may be formed to penetrate the second interlayer insulating layer 120 and a portion of the upper source/drain pattern SD2. A bottom surface of the second upper hole UH2 may be in the upper source/drain pattern SD2.

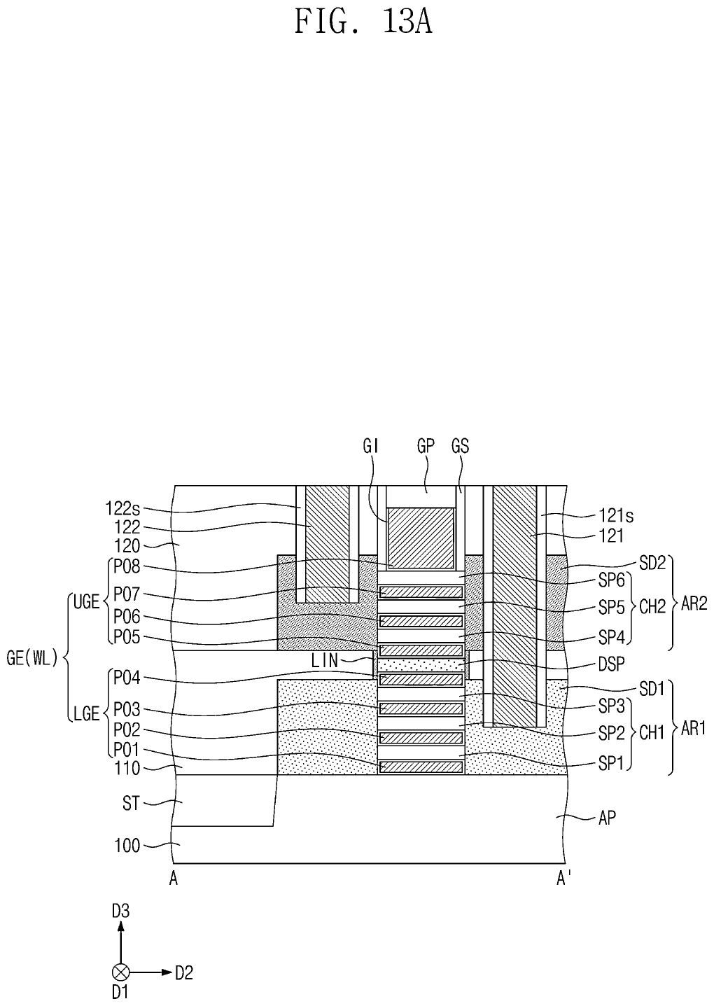

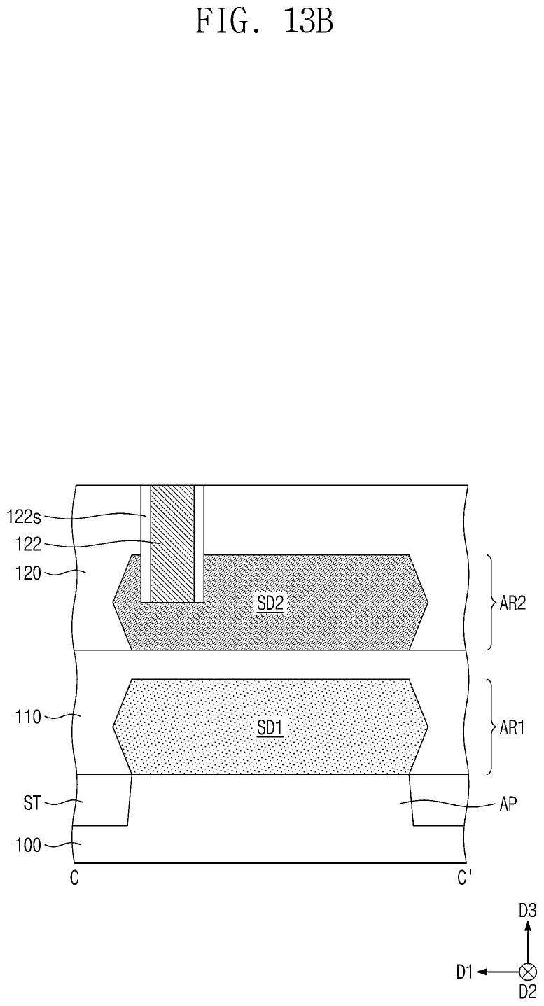

Referring to FIGS. 13A and 13B, the first upper contact 121, the first upper separation structure 121s, the second upper contact 122, and the second upper separation structure 122s may be formed.

In an embodiment, the formation of the first upper separation structure 121s may include forming a first upper separation layer (not shown) to conformally cover an inner side surface and a bottom surface of the first upper hole UH1 and performing an anisotropic etching process to remove a portion of the first upper separation layer covering the bottom surface of the first upper hole UH1. The first upper separation structure 121s may conformally cover the inner side surface of the first upper hole UH1. The first upper separation structure 121s may not cover the bottom surface of the first upper hole UH1 and may expose the lower source/drain patterns SD1.

The first upper contact 121 may be formed in a remaining portion of the first upper hole UH1. In an embodiment, the formation of the first upper contact 121 may include forming a first upper layer (not shown) to fill the remaining portion of the first upper hole UH1 and recessing the first upper layer to expose the top surface of the second interlayer insulating layer 120. A bottom surface of the first upper contact 121 may be in contact with the lower source/drain patterns SD1.

The second upper separation structure 122s and the second upper contact 122 may be formed by substantially the same method as the first upper separation structure 121s and the first upper contact 121. However, in an embodiment, the second upper separation structure 122s may not be formed. In this case, the second upper contact 122 may be formed to fill the entirety of the second upper hole UH2. The bottom surface of the second upper contact 122 may be in contact with the upper source/drain patterns SD2.

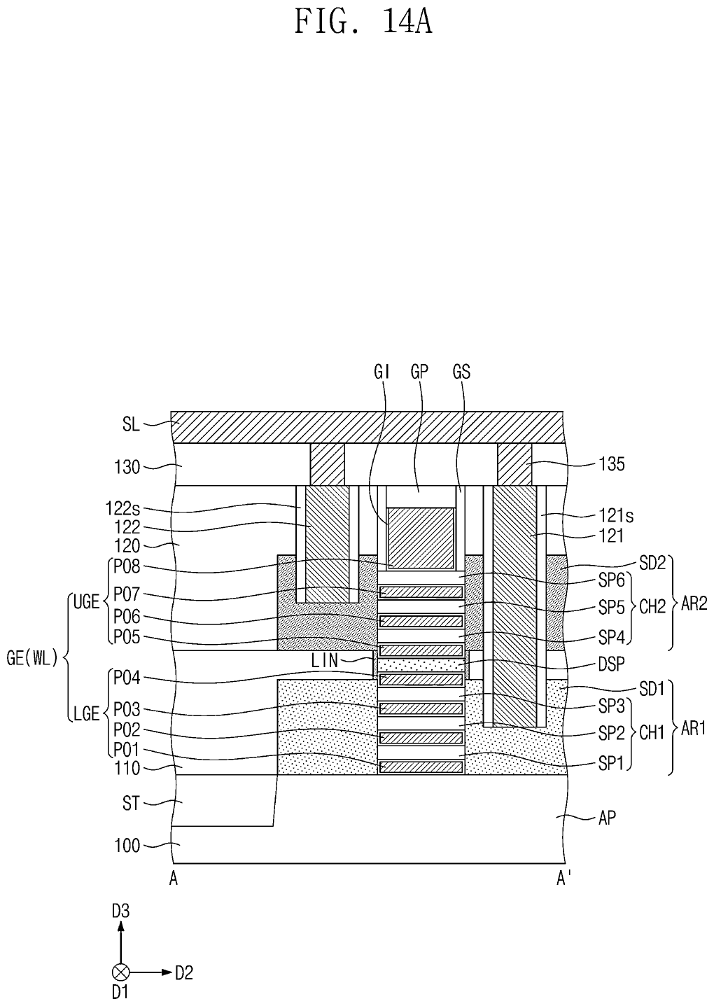

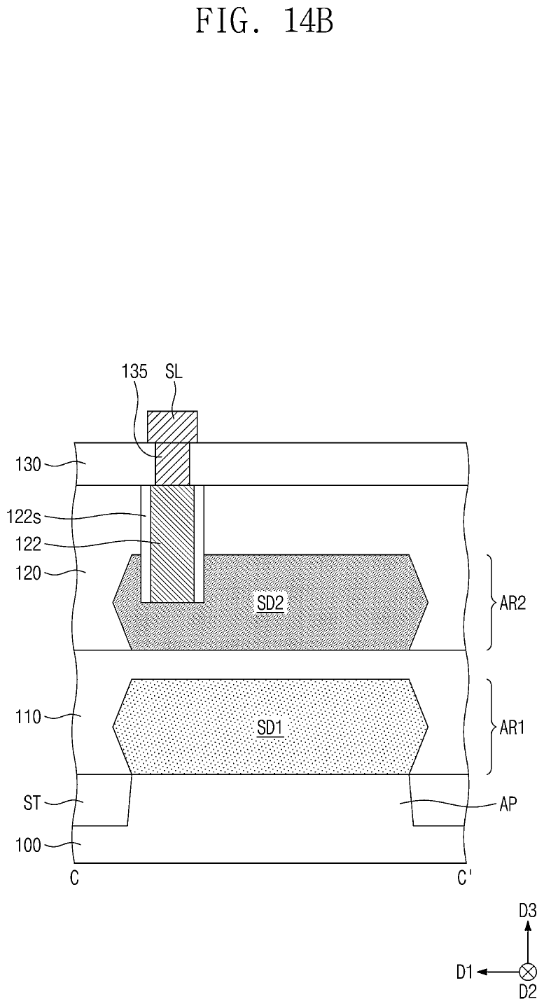

Referring to FIGS. 14A and 14B, the third interlayer insulating layer 130 may be formed on the second interlayer insulating layer 120. Although not shown, the gate contact GC, which is coupled to the gate electrode GE, may be formed to penetrate the third interlayer insulating layer 130 and the gate capping pattern GP. The source contacts 135, which are respectively electrically connected to the first and second upper contacts 121 and 122, may be formed in the third interlayer insulating layer 130.

The source line SL may be formed on the third interlayer insulating layer 130. In an embodiment, the formation of the source line SL may include forming a source line layer (not shown) and patterning the source line layer. The source line SL may be extended in the second direction D2 to cross the gate electrode GE. A bottom surface of the source line SL may be in electrical contact with top surfaces of the source contacts 135.

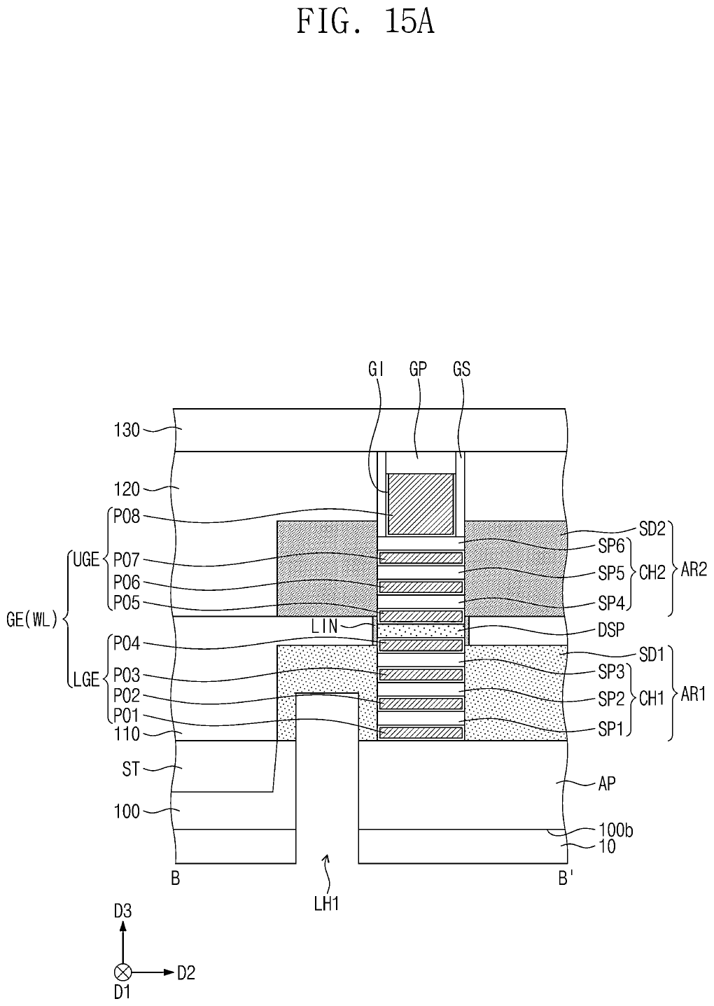

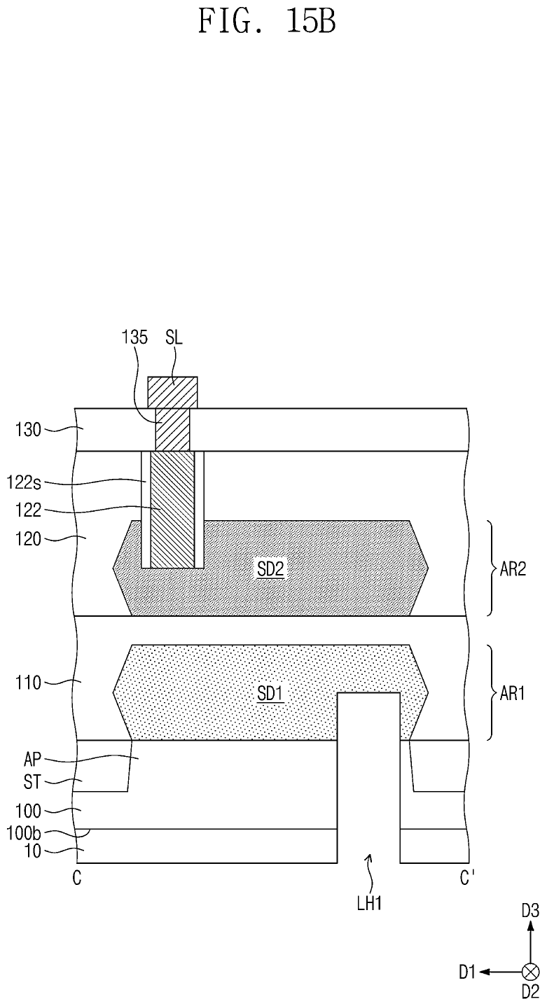

Referring to FIGS. 15A and 15B, the first lower insulating layer 10 may be formed on the bottom surface 100b of the substrate 100.

A first lower hole (i.e., opening) LH1 may be formed after the formation of the first lower insulating layer 10. The first lower hole LH1 may be formed at a side of the gate electrode GE. The first lower hole LH1 may extend in the third direction D3 from the bottom surface of the first lower insulating layer 10 to the lower source/drain patterns SD1. The first lower hole LH1 may be formed to penetrate (i.e., extend in) the first lower insulating layer 10, the substrate 100, and a portion of the lower source/drain pattern SD1. A top surface of the first lower hole LH1 may be in the lower source/drain pattern SD1.

Referring to FIGS. 16A and 16B, the first lower separation structure 11s and the first lower contact 11 may be formed in the first lower hole LH1. In an embodiment, the formation of the first lower separation structure 11s may include forming a first lower separation layer (not shown) to conformally cover an inner side surface and a top surface of the first lower hole LH1 and performing an anisotropic etching process to remove a portion of the first lower separation layer covering the top surface of the first lower hole LH1. The first lower separation structure 11s may be formed to conformally cover the inner side surface of the first lower hole LH1. The first lower separation structure 11s may not cover the top surface of the first lower hole LH1 and may expose the lower source/drain patterns SD1. However, in an embodiment, the formation of the first lower separation structure 11s may be omitted.

The first lower contact 11 may be formed in a remaining portion of the first lower hole LH1. In an embodiment, the formation of the first lower contact 11 may include forming a first lower layer (not shown) to fill the remaining portion of the first lower hole LH1 and recessing the first lower layer to expose the bottom surface of the first lower insulating layer 10. The top surface of the first lower contact 11 may be in contact with the lower source/drain patterns SD1. However, according to an embodiment of the inventive concept, the first lower separation structure 11s may not be formed, and in this case, the first lower contact 11 may be formed to fill the entirety of the first lower hole LH1.

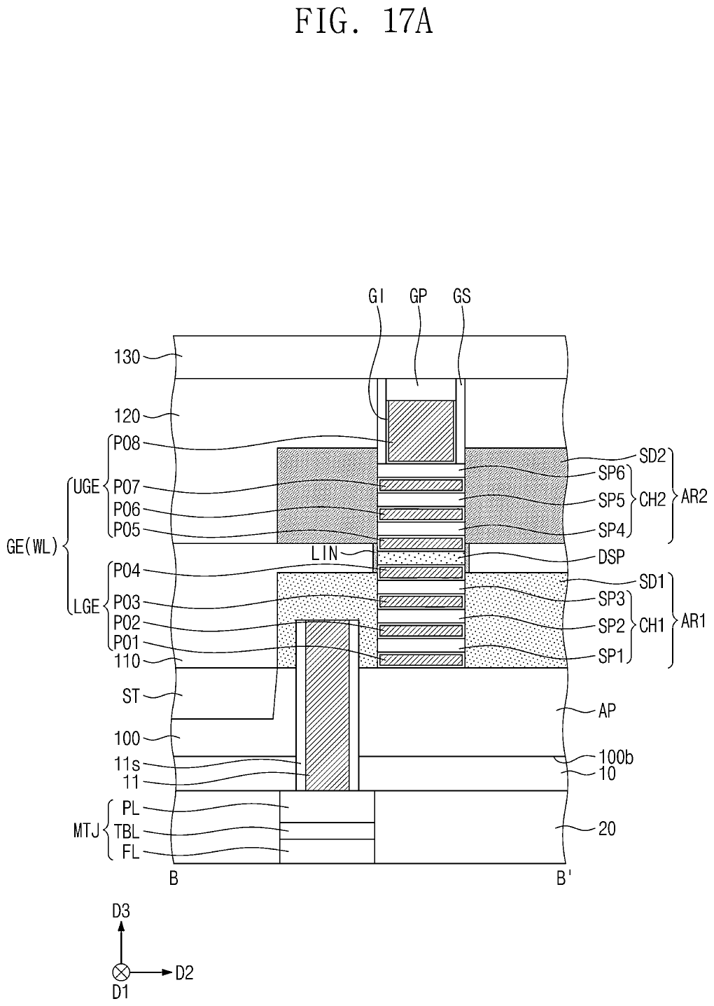

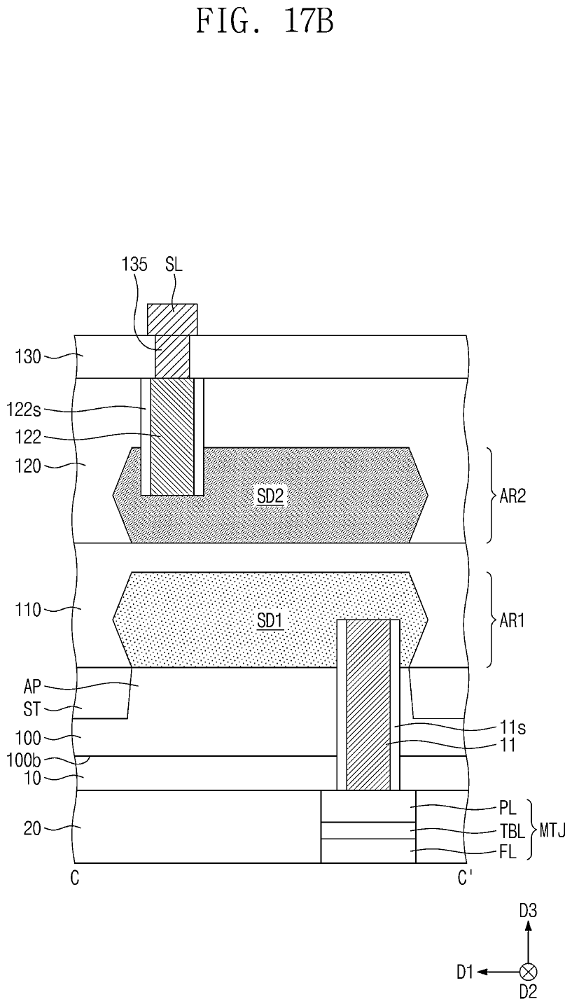

Referring to FIGS. 17A and 17B, the magnetic tunnel junction pattern MTJ may be formed. The magnetic tunnel junction pattern MTJ may be formed in a region, which is vertically overlapped with the first lower contact 11, and may be in direct contact with a bottom surface of the first lower contact 11. In an embodiment, the formation of the magnetic tunnel junction pattern MTJ may include sequentially stacking a pinned magnetic layer (not shown), a tunnel barrier layer (not shown), and a free magnetic layer (not shown) on the first lower insulating layer 10, forming a mask pattern on the free magnetic layer, sequentially and anisotropically etching the free magnetic layer, the tunnel barrier layer, and the pinned magnetic layer using the mask pattern as an etch mask to expose the bottom surface of the first lower insulating layer 10, and removing the mask pattern.

The second lower insulating layer 20 may be formed to cover the first lower insulating layer 10 and the magnetic tunnel junction pattern MTJ. In an embodiment, the formation of the second lower insulating layer 20 may include forming an insulating layer (not shown) on the first lower insulating layer 10 and the magnetic tunnel junction pattern MTJ and planarizing the insulating layer to expose the magnetic tunnel junction pattern MTJ.

Referring to FIGS. 18A and 18B, a second lower hole LH2 may be formed. The second lower hole LH2 may be spaced apart from the first lower contact 11 in the second direction D2, with the gate electrode GE interposed therebetween. The second lower hole LH2 may extend in the third direction D3 from the second lower insulating layer 20 to the upper source/drain patterns SD2. The second lower hole LH2 may be formed to penetrate (i.e., extend in) the second lower insulating layer 20, the first lower insulating layer 10, the substrate 100, the lower source/drain pattern SD1, the first interlayer insulating layer 110, and a portion of the upper source/drain pattern SD2. A top surface of the second lower hole LH2 may be in the upper source/drain pattern SD2.

Referring to FIGS. 19A and 19B, the second lower separation structure 12s and the second lower contact 12 may be formed. In an embodiment, the formation of the second lower separation structure 12s may include forming a second lower separation layer (not shown) to conformally cover an inner side surface and a top surface of the second lower hole LH2 and performing an anisotropic etching process to remove a portion of the second lower separation layer covering the top surface of the second lower hole LH2. The second lower separation structure 12s may conformally cover the inner side surface of the second lower hole LH2. The second lower separation structure 12s may not cover the top surface of the second lower hole LH2 and may expose the upper source/drain patterns SD2.

The second lower contact 12 may be formed in a remaining portion of the second lower hole LH2. In an embodiment, the formation of the second lower contact 12 may include forming a second lower layer (not shown) to fill the remaining portion of the second lower hole LH2 and recessing the second lower layer to expose the bottom surface of the second lower insulating layer 20. A top surface of the second lower contact 12 may be in contact with the upper source/drain pattern SD2.

Referring back to FIGS. 3 and 4A to 4E, the spin-orbit torque line SOT may be formed on the second lower insulating layer 20. The spin-orbit torque line SOT may be in contact with the bottom surface of the magnetic tunnel junction pattern MTJ and the bottom surface of the second lower contact 12. In an embodiment, the formation of the spin-orbit torque line SOT may include forming a spin-orbit torque line layer (not shown) and patterning the spin-orbit torque line layer.

The third lower insulating layer 30 may be formed on the bottom surface of the second lower insulating layer 20 to cover the spin-orbit torque line SOT. The bit line contact BC and the bit line BL may be formed in the third lower insulating layer 30. The power delivery network layer PDN or an additional interconnection layer may be formed on a bottom surface of the bit line BL.

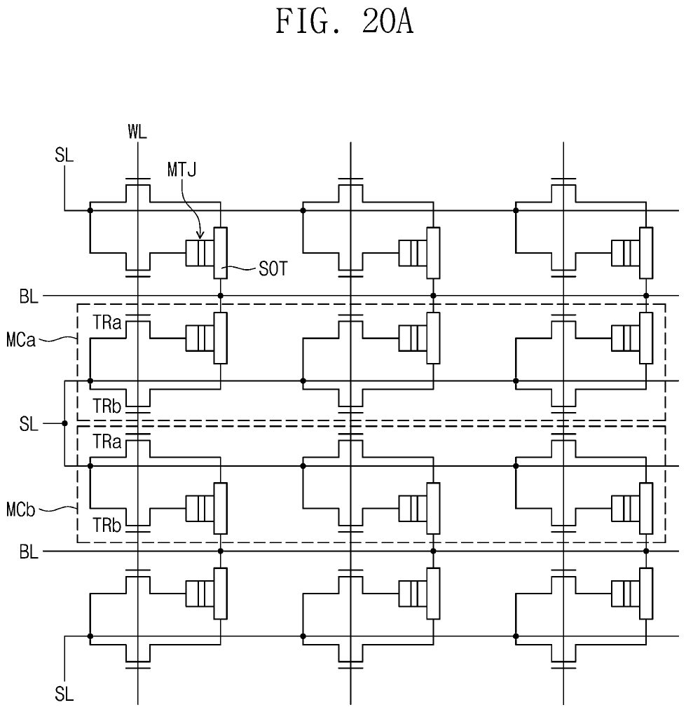

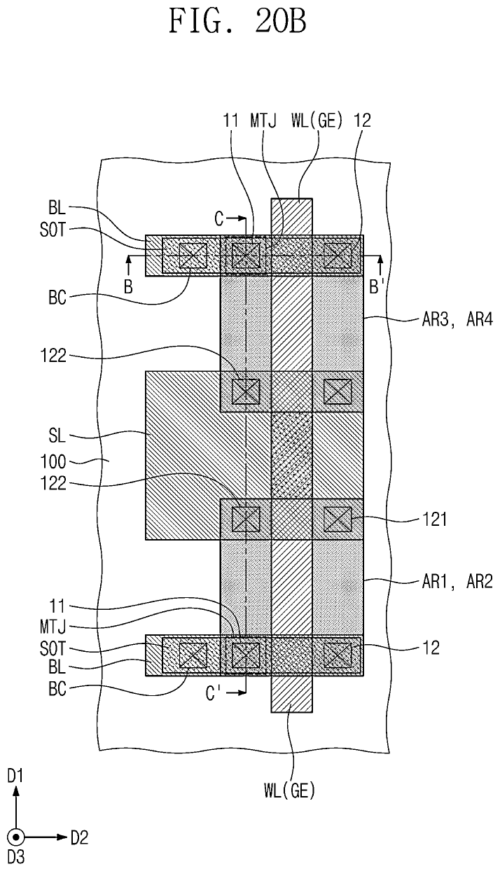

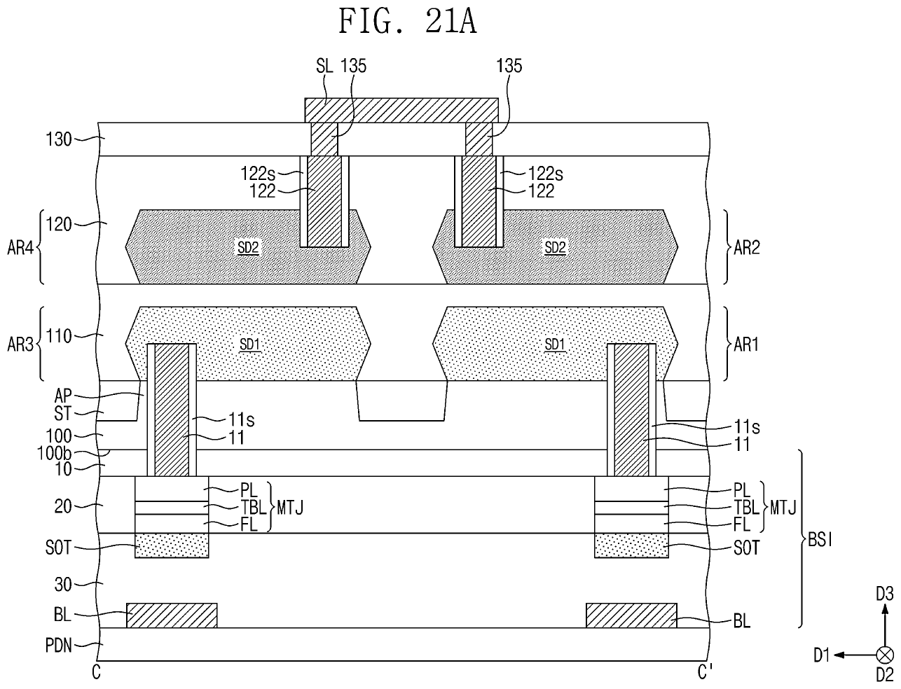

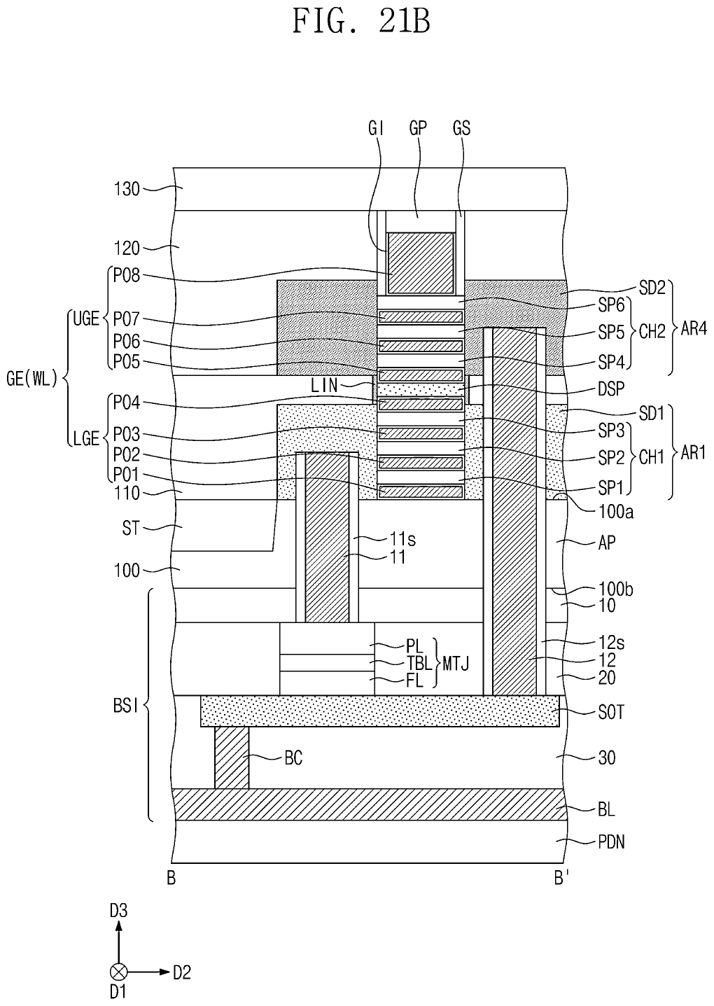

FIG. 20A is a schematic circuit diagram illustrating a cell array of a magnetic memory device according to an embodiment of the inventive concept. FIG. 20B is a plan view illustrating a magnetic memory device according to an embodiment of the inventive concept. FIGS. 21A and 21B are sectional views taken along lines C-C′ and B-B′ of FIG. 20B, respectively. For concise description, a previously described element may be identified by the same reference number without repeating an overlapping description thereof.

Referring to FIGS. 20A and 20B, the cell array may include a plurality of word lines WL, a plurality of bit lines BL, a plurality of source lines SL, and a plurality of memory cells MC.

Each of the memory cells MC may include the magnetic tunnel junction pattern MTJ, the spin-orbit torque line SOT, the upper transistor TRa, and the lower transistor TRb. In the embodiment of FIGS. 20A and 20B, even-numbered row memory cells MCa and odd-numbered row memory cells MCb may be disposed in a symmetrical manner, when compared with the structure of FIGS. 1A and 1B. In an embodiment, referring to FIGS. 20A and 20B, the lower transistor TRb of the even-numbered row memory cell MCa and the upper transistor TRa of the odd-numbered row memory cell MCb may be connected in common to the source line SL.

Referring to FIGS. 20B and 21A and 21B, a third active region AR3 may be spaced apart from the first active region AR1 in the first direction D1. The third active region AR3 may include the lower channel pattern CH1 and the lower source/drain patterns SD1. The lower channel pattern CH1 and the lower source/drain patterns SD1 of the third active region AR3 may have substantially the same features as the lower channel pattern CH1 and the lower source/drain patterns SD1 of the first active region AR1.

A fourth active region AR4 may be stacked on the third active region AR3 in the third direction D3 and may be spaced apart from the second active region AR2 in the first direction D1. The fourth active region AR4 may include the upper channel pattern CH2 and the upper source/drain pattern SD2. The upper channel pattern CH2 and the upper source/drain patterns SD2 of the fourth active region AR4 may have substantially the same features as the upper channel pattern CH2 and the upper source/drain patterns SD2 of the second active region AR2.

The gate electrode GE may be disposed on the lower channel pattern CH1 of the third active region AR3 and the upper channel pattern CH2 of the fourth active region AR4. The gate electrode GE may be the same as the gate electrode GE, which is disposed on the lower channel pattern CH1 of the first active region AR1 and the upper channel pattern CH2 of the second active region AR2. The gate electrode GE may correspond to the word line WL of FIG. 20B. The gate electrode GE may extend in the first direction D1 to cross the first and second active regions AR1 and AR2, which are vertically stacked, and the third and fourth active regions AR3 and AR4, which are vertically stacked.

The first interlayer insulating layer 110 may be disposed on the substrate 100. The first interlayer insulating layer 110 may cover the lower source/drain patterns SD1 of the first and third active regions AR1 and AR3.

The second interlayer insulating layer 120 may be disposed on the first interlayer insulating layer 110. The second interlayer insulating layer 120 may cover the upper source/drain patterns SD2 of the second and fourth active regions AR2 and AR4.

Although not shown, the first upper contacts 121 and the first upper separation structures 121s, which are respectively connected to the lower source/drain patterns SD1 of the first and third active regions AR1 and AR3, may extend in the third direction D3 into the second interlayer insulating layer 120, the upper source/drain patterns SD2 of the second and fourth active regions AR2 and AR4, and a portion of the first interlayer insulating layer 110.

The second upper contacts 122 and the second upper separation structures 122s, which are respectively electrically connected to the upper source/drain patterns SD2 of the second and fourth active regions AR2 and AR4, may extend in the third direction D3 into a portion of the second interlayer insulating layer 120. However, in an embodiment, the second upper separation structures 122s may not be provided.

The first and second upper contacts 121 and 122 and the first and second upper separation structures 121s and 122s may be configured to have substantially the same features as those in the embodiment of FIGS. 3 and 4A to 4E.

The third interlayer insulating layer 130 may be disposed on the second interlayer insulating layer 120. The source contacts 135, which are respectively connected to the first and second upper contacts 121 and 122, may be disposed in the third interlayer insulating layer 130.

The source line SL, which extend in the second direction D2, may be disposed on the third interlayer insulating layer 130. The source line SL may extend in the first direction D1 and may be commonly connected to the source contacts 135. When viewed in a plan view, the source line SL may be vertically overlapped with portions of the first and second active regions AR1 and AR2 and may be vertically overlapped with portions of the third and fourth active regions AR3 and AR4.

The first lower insulating layer 10 may be disposed on the bottom surface 100b of the substrate 100. The first lower contacts 11, which are respectively electrically connected to the lower source/drain patterns SD1 of the first and third active region AR1 and AR3, may extend in the third direction D3 in the first lower insulating layer 10 and the substrate 100. Each of the first lower contacts 11 may extend in the third direction D3 from the bottom surface of the first lower insulating layer 10 to penetrate the first lower insulating layer 10, the substrate 100, and a portion of the lower source/drain pattern SD1. Top surfaces of the first lower contacts 11 may be in the lower source/drain patterns SD1, respectively. The first lower separation structures 11s may extend around the first lower contacts 11. However, in an embodiment, the first lower separation structures 11s may not exist, unlike the illustrated structure. The first lower contacts 11 may be electrically and selectively connected to the lower source/drain patterns SD1 of the first and third active region AR1 and AR3, respectively.

The second lower insulating layer 20 may be disposed on the first lower insulating layer 10. The magnetic tunnel junction patterns MTJ may be disposed in the second lower insulating layer 20. The magnetic tunnel junction patterns MTJ may be in contact with and connected to the first lower contacts 11, respectively, which are connected to the first and third active regions AR1 and AR3. When viewed in a plan view, the magnetic tunnel junction patterns MTJ may be vertically overlapped with the first lower contacts 11, respectively. The magnetic tunnel junction patterns MTJ may be configured to have substantially the same features as the magnetic tunnel junction pattern MTJ described with reference to FIGS. 3 and 4A to 4E. The magnetic tunnel junction patterns MTJ may be electrically connected to the lower source/drain patterns SD1 of the first and third active regions AR1 and AR3, respectively, through the first lower contacts 11.

Although not shown, the second lower contacts 12, which are respectively connected to the upper source/drain patterns SD2 of the second and fourth active regions AR2 and AR4, may extend in the third direction D3 into the second lower insulating layer 20. The second lower contacts 12 may be configured to have substantially the same features as the second lower contact 12 described with reference to FIGS. 3 and 4A to 4E.

The spin-orbit torque lines SOT may be disposed on the second lower insulating layer 20. The spin-orbit torque lines SOT may be in contact with and connected to the magnetic tunnel junction patterns MTJ and the second lower contacts 12, respectively, which are respectively connected to the second and fourth active regions AR2 and AR4. The spin-orbit torque lines SOT may be electrically connected to the upper source/drain patterns SD2 of the second and fourth active regions AR2 and AR4, respectively, through the second lower contacts 12.

The third lower insulating layer 30 may be disposed on the second lower insulating layer 20. The bit lines BL may be disposed in the third lower insulating layer 30. The power delivery network layer PDN or an additional interconnection layer may be disposed on the third lower insulating layer 30. The third lower insulating layer 30, the bit lines BL, and the power delivery network layer PDN (or the additional interconnection layer) may be configured to have substantially the same features as those in the embodiment described with reference to FIGS. 3 and 4A to 4E.

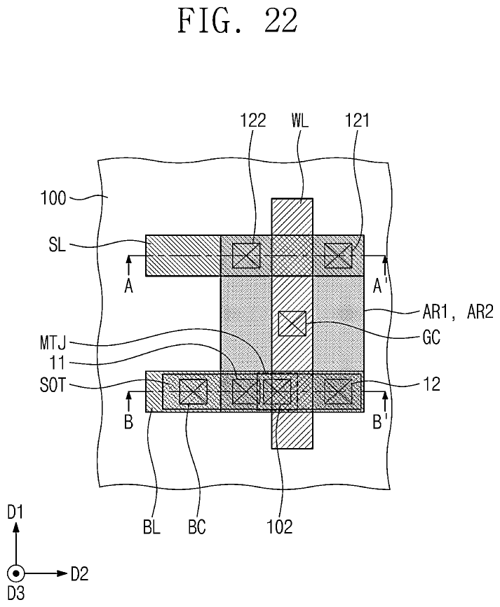

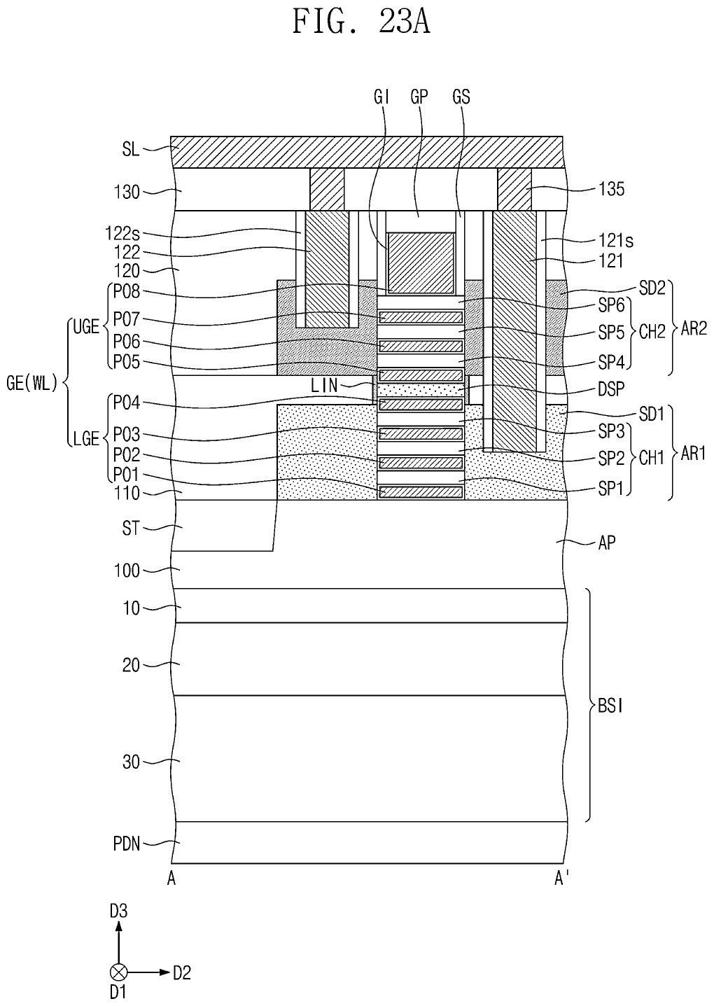

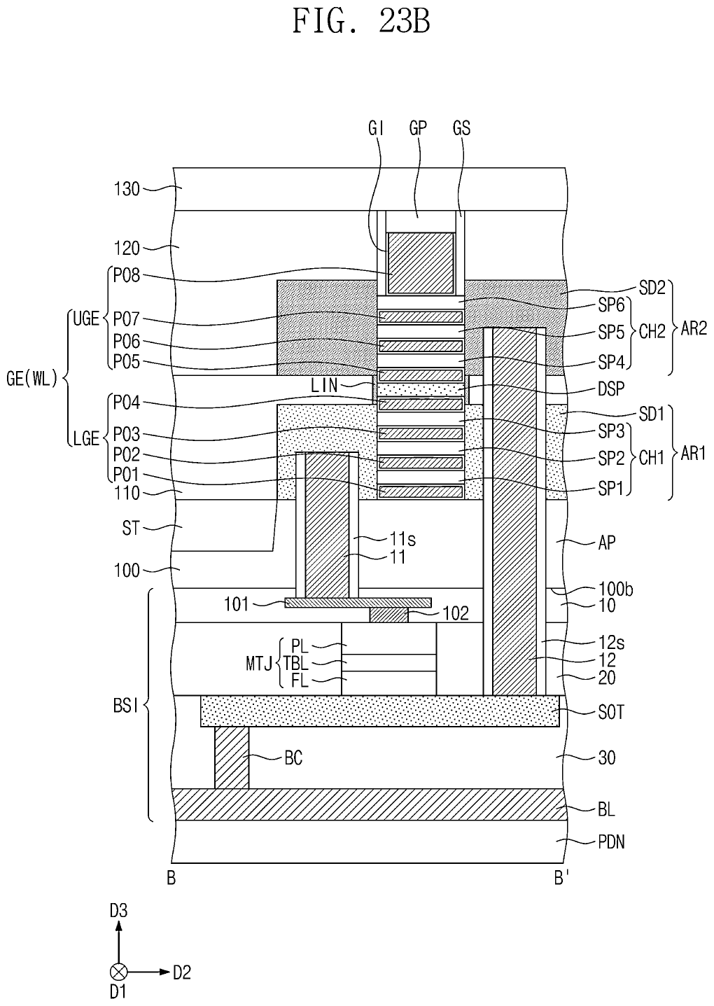

In the embodiment of FIGS. 20A, 20B, 21A and 21B, the source line SL may be commonly connected to adjacent ones of the memory cells MC. That is, by increasing an area of the source line SL, it may be possible to lower the resistance of the source line SL. FIG. 22 is a plan view illustrating a magnetic memory device according to an embodiment of the inventive concept. FIGS. 23A and 23B are cross-sectional views taken along lines A-A′ and B-B′ of FIG. 22, respectively. For concise description, a previously described element may be identified by the same reference number without repeating an overlapping description thereof.

Referring to FIGS. 22, 23A, and 23B, the interlayer interconnection layer including an interlayer interconnection line 101 and an interlayer interconnection contact 102 may be disposed in the first lower insulating layer 10. In detail, the interlayer interconnection line 101 and the interlayer interconnection contact 102 may be disposed between the first lower contact 11 and the magnetic tunnel junction pattern MTJ. The first lower contact 11 and the interlayer interconnection line 101 may be in contact with and connected to each other. The interlayer interconnection line 101 and the interlayer interconnection contact 102 may be in contact with and connected to each other. The interlayer interconnection contact 102 and the magnetic tunnel junction pattern MTJ may be in contact with and connected to each other. That is, the magnetic tunnel junction pattern MTJ may be connected to the first lower contact 11 through the interlayer interconnection contact 102 and the interlayer interconnection line 101.

The magnetic tunnel junction pattern MTJ may not be vertically overlapped with the first lower contact 11. That is, the magnetic tunnel junction pattern MTJ may not be directly connected to or in direct contact with the first lower contact 11. This is because the magnetic tunnel junction pattern MTJ is connected to the first lower contact 11 through the interlayer interconnection contact 102 and the interlayer interconnection line 101. Thus, the magnetic tunnel junction pattern MTJ may exist in a region where the spin-orbit torque line SOT and the interlayer interconnection layer are in contact with each other.

The interlayer interconnection line 101 and the interlayer interconnection contact 102 may be formed of or include at least one of metallic materials (e.g., tungsten, titanium, tantalum, and cobalt) and/or conductive metal nitrides (e.g., titanium nitride, tantalum nitride, and tungsten nitride), although embodiments are not limited thereto.

In the embodiment of FIGS. 22, 23A, and 23B, since the interlayer interconnection layer includes the interlayer interconnection line 101 and the interlayer interconnection contact 102, it may be possible to increase a degree of freedom in the location of the magnetic tunnel junction pattern MTJ. That is, unlike the embodiment of FIGS. 3 and 4A to 4E, the magnetic tunnel junction pattern MTJ may exist in a region that is not vertically overlapped with the first lower contact 11. Thus, it may be possible to more easily fabricate the magnetic memory device.

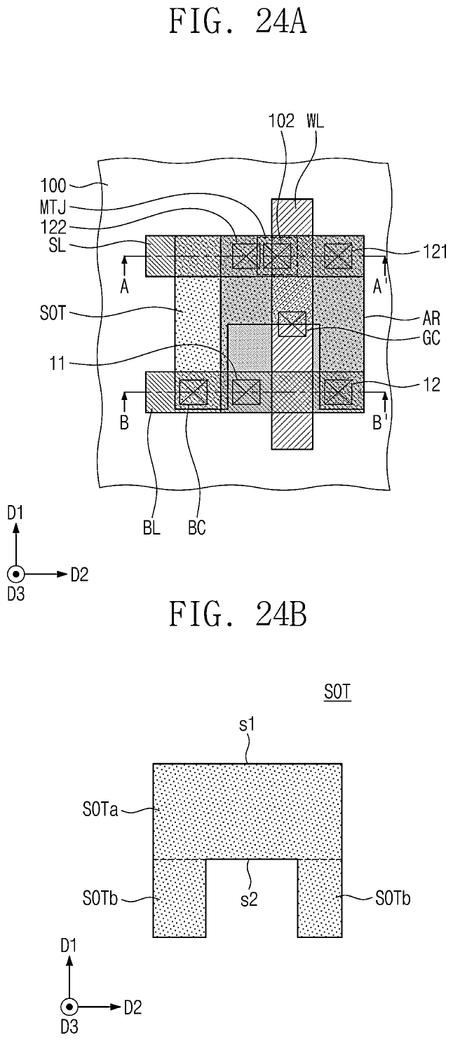

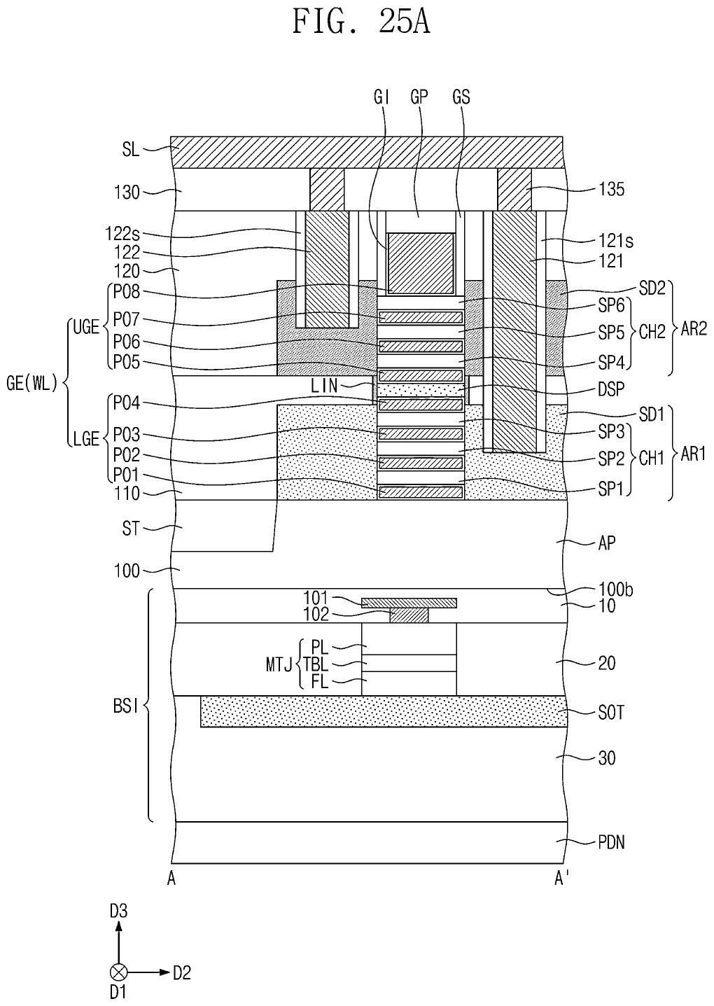

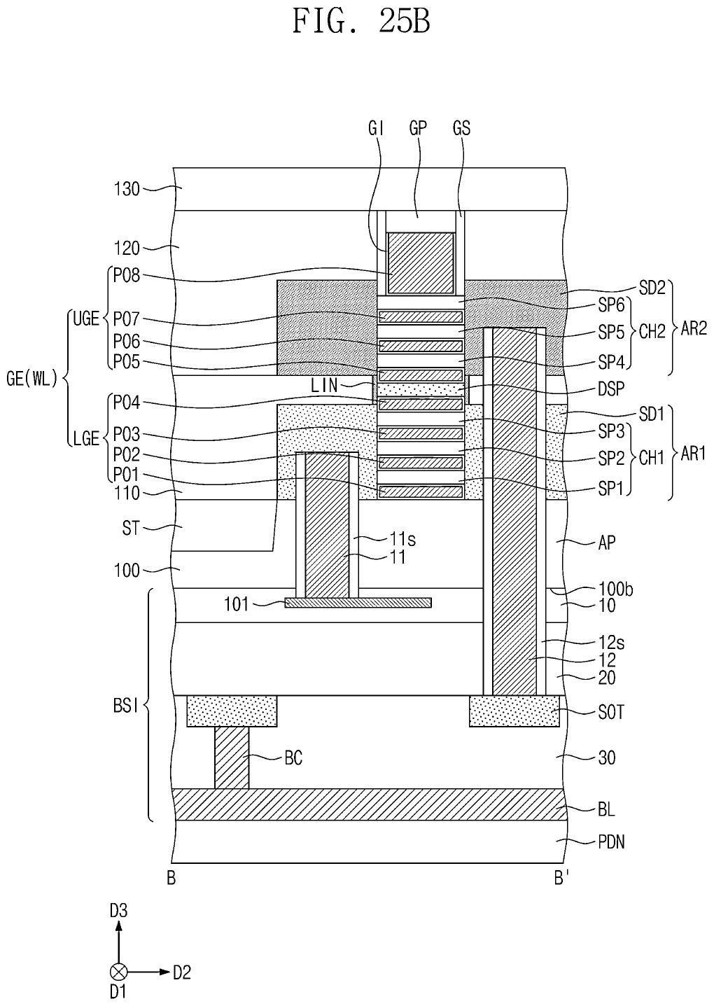

FIG. 24A is a plan view illustrating a magnetic memory device according to an embodiment of the inventive concept. FIG. 24B is a plan view illustrating a portion of a spin-orbit torque line of FIG. 24A. FIGS. 25A and 25B are cross-sectional views taken along lines A-A′ and B-B′ of FIG. 24A, respectively. For concise description, a previously described element may be identified by the same reference number without repeating an overlapping description thereof.

Referring to FIGS. 24A and 24B, the spin-orbit torque line SOT may extend to a region that is vertically overlapped with the source line SL. In detail, the spin-orbit torque line SOT may include a first portion SOTa, which extends in the first and second directions D1 and D2 (i.e., parallel to an upper surface of the substrate 100). The first portion SOTa of the spin-orbit torque line SOT may have a first surface s1 and a second surface s2, which are opposite to each other in the first direction D1. The spin-orbit torque line SOT may include second portions SOTb, which extend in the first direction D1 from opposite ends of the second surface s2. When viewed in a plan view, the first portion SOTa of the spin-orbit torque line SOT may be vertically overlapped with a portion of the source line SL, and the second portions SOTb may be vertically overlapped with portions of the bit line BL.

Referring to FIGS. 24A, 25A, and 25B, the interlayer interconnection layer including the interlayer interconnection line 101 and the interlayer interconnection contact 102 may be disposed in the first lower insulating layer 10. The interlayer interconnection contact 102 may be disposed in a region where is not overlapped with the first lower contact 11 vertically. The interlayer interconnection line 101 may be in contact with the interlayer interconnection contact 102 and the first lower contact 11. Here, the interlayer interconnection line 101 may extend in the first and second directions D1 and D2 to make contact with both the interlayer interconnection contact 102 and the first lower contact 11. In an embodiment, when viewed in a plan view, the interlayer interconnection line 101 may have a rectangular shape or the shape of letter ‘L’.

The magnetic tunnel junction pattern MTJ may not be vertically overlapped with the first lower contact 11. The magnetic tunnel junction pattern MJT may be in contact with the spin-orbit torque line SOT. The magnetic tunnel junction pattern MTJ may be in contact with and connected to the interlayer interconnection contact 102. In an embodiment, the magnetic tunnel junction pattern MTJ may be provided in a region which is in contact with both the spin-orbit torque line SOT and the interlayer interconnection contact 102.

The second portions SOTb of the spin-orbit torque line SOT may be in contact with and connected to the bit line contact BC and the second lower contact 12, respectively. In an embodiment, the spin-orbit torque line SOT may have a rectangular shape that is extended in the first and second directions D1 and D2, although not shown.

In the embodiment of FIGS. 24A, 25A, and 25B, owing to the structure of the lower interconnection layer BSI and the spin-orbit torque line SOT, it may be possible to increase a degree of freedom in arranging the magnetic tunnel junction pattern MTJ. That is, the magnetic tunnel junction pattern MTJ may not be directly connected to or in direct contact with the first lower contact 11. This is because the magnetic tunnel junction pattern MTJ is connected to the first lower contact 11 through the interlayer interconnection contact 102 and the interlayer interconnection line 101. In addition, owing to the shape of the spin-orbit torque line SOT, it may be possible to increase a degree of freedom in arranging the magnetic tunnel junction pattern MTJ. Thus, it may be possible to easily fabricate the magnetic memory device.

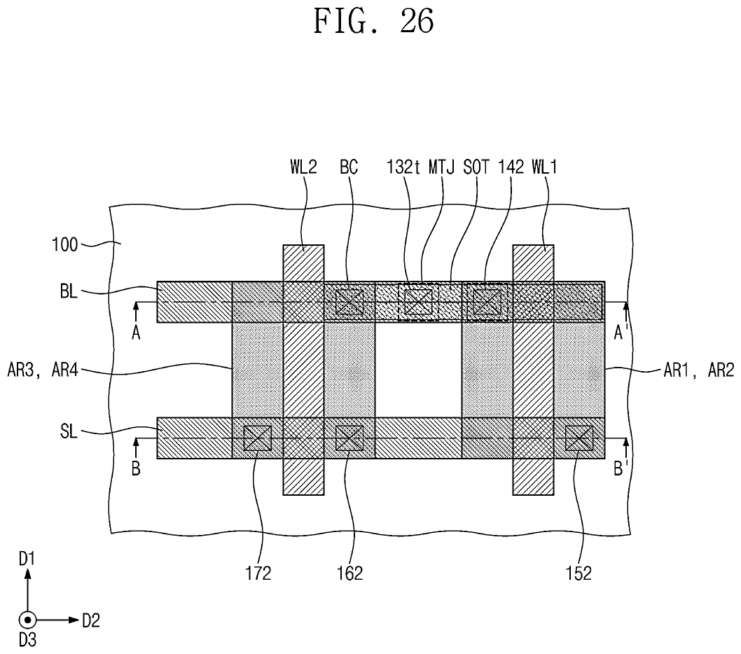

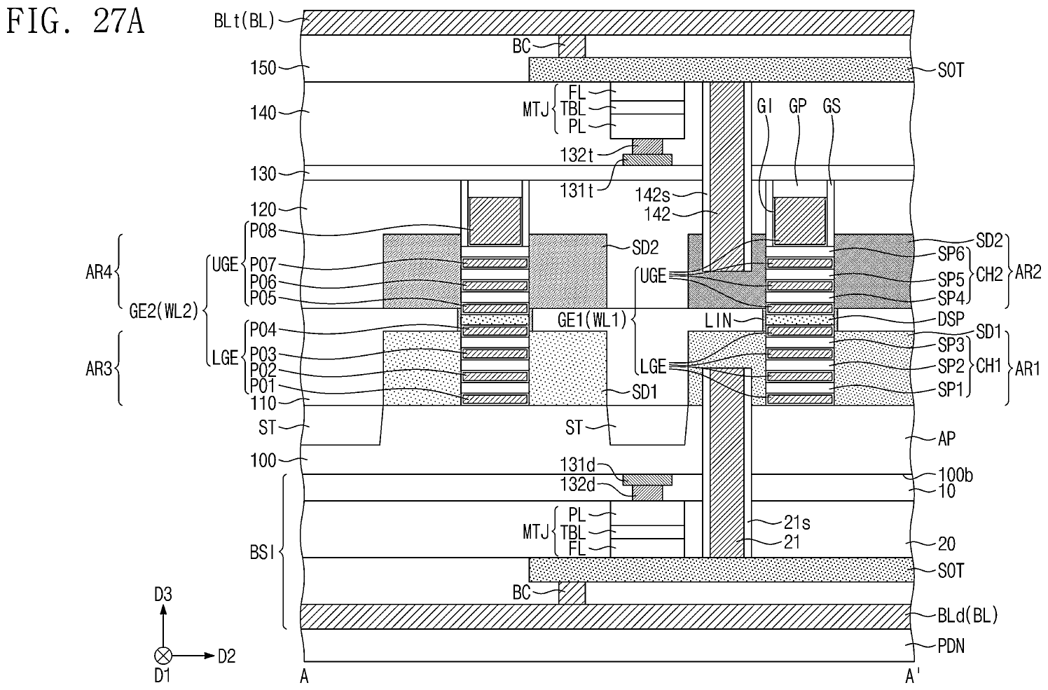

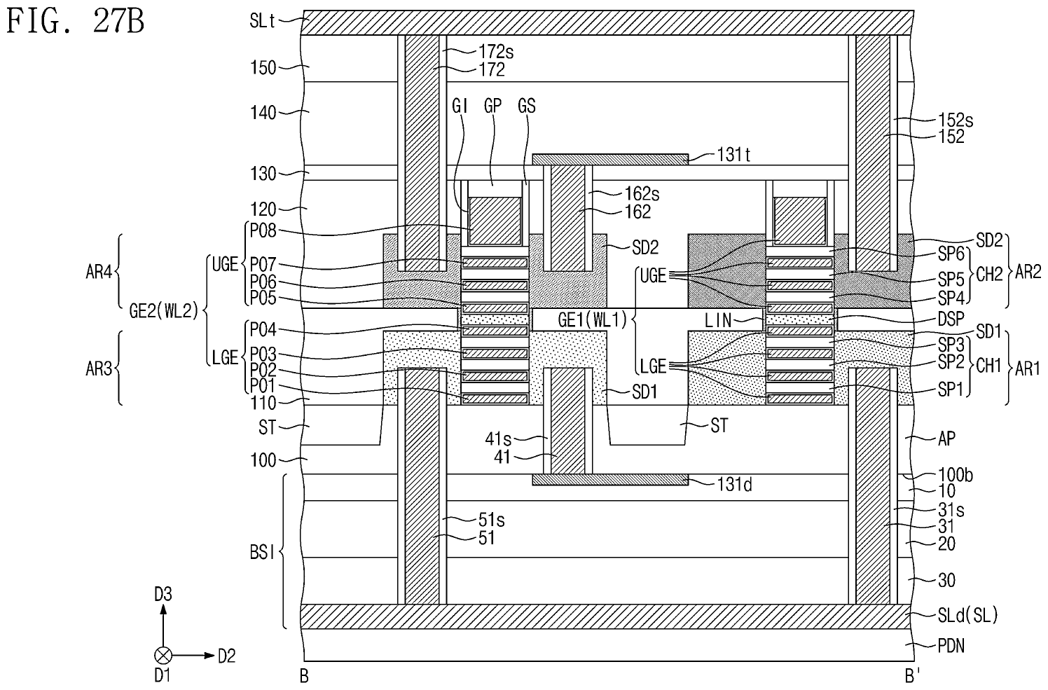

FIG. 26 is a plan view illustrating a magnetic memory device according to an embodiment of the inventive concept. FIGS. 27A and 27B are cross-sectional views taken along lines A-A′ and B-B′ of FIG. 26, respectively. For concise description, a previously described element may be identified by the same reference number without repeating an overlapping description thereof.

Referring to FIGS. 26, 27A, and 27B, the third active region AR3 may be spaced apart from the first active region AR1 in the second direction D2. The third active region AR3 may include the lower channel pattern CH1 and the lower source/drain patterns SD1. The lower channel pattern CH1 and the lower source/drain patterns SD1 of the third active region AR3 may have substantially the same features as the lower channel pattern CH1 and the lower source/drain patterns SD1 of the first active region AR1.

The fourth active region AR4 may be stacked on the third active region AR3 in the third direction D3 and may be spaced apart from the second active region AR2 in the second direction D2. The fourth active region AR4 may include the upper channel pattern CH2 and the upper source/drain patterns SD2. The upper channel pattern CH2 and the upper source/drain patterns SD2 of the fourth active region AR4 may have substantially the same features as the upper channel pattern CH2 and the upper source/drain patterns SD2 of the second active region AR2.

A first gate electrode GE1 may be disposed on the lower channel pattern CH1 of the first active region AR1 and the upper channel pattern CH2 of the second active region AR2. A second gate electrode GE2 may be disposed on the lower channel pattern CH1 of the third active region AR3 and the upper channel pattern CH2 of the fourth active region AR4. The first and second gate electrodes GE1 and GE2 may have substantially the same features as the gate electrode GE described with reference to FIGS. 3 and 4A to 4E. The first gate electrode GE1 may correspond to a first word line WL1 of FIG. 26. The second gate electrode GE2 may correspond to a second word line WL2 of FIG. 26. The first and second gate electrodes GE1 and GE2 may extend in the first direction D1 to cross the bit line BL and the source line SL.

The first interlayer insulating layer 110 may be disposed on the substrate 100. The first interlayer insulating layer 110 may cover the lower source/drain patterns SD1 of the first and third active regions AR1 and AR3.

The second interlayer insulating layer 120 may be disposed on the first interlayer insulating layer 110. The second interlayer insulating layer 120 may cover the upper source/drain patterns SD2 of the second and fourth active regions AR2 and AR4.

The third interlayer insulating layer 130 may be disposed on the second interlayer insulating layer 120. A fourth interlayer insulating layer 140 may be disposed on the third interlayer insulating layer 130. A fifth interlayer insulating layer 150 may be disposed on the fourth interlayer insulating layer 140. An upper source line SLt and an upper bit line BLt may be disposed on the fifth interlayer insulating layer 150. The upper source line SLt and the upper bit line BLt may be spaced apart from each other in the first direction D1 and may be bar-shaped patterns that extend in the second direction D2.

A first upper active contact 142 may be disposed in the fourth interlayer insulating layer 140 and may be connected to the upper source/drain pattern SD2 of the second active region AR2. Referring to FIG. 26, the first upper active contact 142 may be disposed at a side of the first word line WL1. In detail, the first upper active contact 142 may extend in the third direction D3 from a top surface of the fourth interlayer insulating layer 140 into the fourth interlayer insulating layer 140, the third interlayer insulating layer 130, the second interlayer insulating layer 120, and a portion of the upper source/drain pattern SD2 of the second active region AR2. A bottom surface of the first upper active contact 142 may be in the upper source/drain pattern SD2 of the second active region AR2.

A first upper active separation structure 142s may extend around the first upper active contact 142. However, in an embodiment, the first upper active separation structure 142s may be omitted, unlike the illustrated structure. The first upper active contact 142 may be electrically and selectively connected to the upper source/drain pattern SD2 of the second active region AR2.

A second upper active contact 152 may be disposed in the fifth interlayer insulating layer 150 and may be electrically connected to the upper source/drain pattern SD2 of the second active region AR2. Referring to FIG. 26, the second upper active contact 152 may be disposed at an opposite side of the first word line WL1 where the first upper active contact 142 is not disposed. When viewed in a plan view, the first word line WL1 may be elongated in the first direction D1, between the first upper active contact 142 and the second upper active contact 152. In detail, the second upper active contact 152 may extend in the third direction D3 from a top surface of the fifth interlayer insulating layer 150 into the fifth interlayer insulating layer 150, the fourth interlayer insulating layer 140, the third interlayer insulating layer 130, the second interlayer insulating layer 120, and a portion of the upper source/drain pattern SD2 of the second active region AR2. A bottom surface of the second upper active contact 152 may be in the upper source/drain pattern SD2 of the second active region AR2.

A second upper active separation structure 152s may extend around the second upper active contact 152. However, in an embodiment, the second upper active separation structure 152s may be omitted, unlike the illustrated structure. The second upper active contact 152 may be electrically and selectively connected to the upper source/drain pattern SD2 of the second active region AR2.

A third upper active contact 162 may be disposed in the third interlayer insulating layer 130 and may be electrically connected to the upper source/drain pattern SD2 of the fourth active region AR4. The third upper active contact 162 may be disposed at a side of the second word line WL2. In detail, the third upper active contact 162 may extend in the third direction D3 from a top surface of the third interlayer insulating layer 130 into the third interlayer insulating layer 130, the second interlayer insulating layer 120, and a portion of the upper source/drain pattern SD2 of the fourth active region AR4. A bottom surface of the third upper active contact 162 may be in the upper source/drain pattern SD2 of the fourth active region AR4.

A third upper active separation structure 162s may extend around the third upper active contact 162. However, in an embodiment, the third upper active separation structure 162s may be omitted, unlike the illustrated structure. The third upper active contact 162 may be electrically and selectively connected to the upper source/drain pattern SD2 of the fourth active region AR4.

A fourth upper active contact 172 may be disposed in the fifth interlayer insulating layer 150 and may be electrically connected to the upper source/drain pattern SD2 of the fourth active region AR4. The fourth upper active contact 172 may be disposed at an opposite side of the second word line WL2 where the third upper active contact 162 is not disposed. When viewed in a plan view, the second word line WL2 may be elongated in the first direction D1, between the third upper active contact 162 and the fourth upper active contact 172. In detail, the fourth upper active contact 172 may extend in the third direction D3 from the top surface of the fifth interlayer insulating layer 150 into the fifth interlayer insulating layer 150, the fourth interlayer insulating layer 140, the third interlayer insulating layer 130, the second interlayer insulating layer 120, and a portion of the upper source/drain pattern SD2 of the fourth active region AR4. A bottom surface of the fourth upper active contact 172 may be in the upper source/drain pattern SD2 of the fourth active region AR4.

A fourth upper active separation structure 172s may extend around the fourth upper active contact 172. However, in an embodiment, the fourth upper active separation structure 172s may be omitted, unlike the illustrated structure. The fourth upper active contact 172 may be electrically and selectively connected to the upper source/drain pattern SD2 of the fourth active region AR4.

The first to fourth upper active contacts 142, 152, 162, and 172 may include a doped semiconductor material and/or a metallic material. The metallic material may be selected from the group consisting of copper (Cu), aluminum (Al), ruthenium (Ru), cobalt (Co), tungsten (W), and molybdenum (Mo), although embodiments are not limited thereto. The first to fourth upper active separation structures 142s, 152s, 162s, and 172s may be formed of or include at least one of silicon-based insulating materials (e.g., silicon oxide and silicon nitride).

The magnetic tunnel junction pattern MTJ may be disposed in the fourth interlayer insulating layer 140. The magnetic tunnel junction pattern MTJ may be configured to have substantially the same features as the magnetic tunnel junction pattern MTJ described with reference to FIGS. 3 and 4A to 4E. The magnetic tunnel junction pattern MTJ may not be vertically overlapped with the third upper active contact 162.

An upper interconnection line 131t and an upper interconnection contact 132t may be disposed in the fourth interlayer insulating layer 140. In detail, the upper interconnection line 131t and the upper interconnection contact 132t may be disposed between the magnetic tunnel junction pattern MTJ and the third upper active contact 162. The upper interconnection line 131t may be in contact with the third upper active contact 162 and the upper interconnection contact 132t. The upper interconnection contact 132t may be in contact with the magnetic tunnel junction pattern MTJ. In an embodiment, the magnetic tunnel junction pattern MTJ may be connected to the upper source/drain patterns SD2 of the fourth active region AR4 through the upper interconnection contact 132t, the upper interconnection line 131t, and the third upper active contact 162. When viewed in a plan view, the upper interconnection line 131t may have a rectangular shape or the shape of letter ‘L’.

The spin-orbit torque line SOT may be disposed on the fourth interlayer insulating layer 140. The spin-orbit torque line SOT may be in contact with the magnetic tunnel junction pattern MTJ and the first upper active contact 142. The spin-orbit torque line SOT may be a bar-shaped pattern that extends in the second direction D2.

The bit line contact BC may be disposed in the fifth interlayer insulating layer 150 to electrically connect the spin-orbit torque line SOT to the upper bit line BLt. The second and fourth upper active contacts 152 and 172 may be in contact with the upper source line SLt.

The lower interconnection layer BSI may be disposed on the bottom surface 100b of the substrate 100. In an embodiment, the lower interconnection layer BSI may include the first lower insulating layer 10, the second lower insulating layer 20, and the third lower insulating layer 30, which are sequentially stacked on the bottom surface 100b of the substrate 100. A lower bit line BLd and a lower source line SLd may be disposed on a bottom surface of the third lower insulating layer 30. The lower bit line BLd and the lower source line SLd may be spaced apart from each other in the first direction D1 and may be bar-shaped patterns that are elongated in the second direction D2. The power delivery network layer PDN or an additional interconnection layer may be disposed on a bottom surface of the lower interconnection layer BSI.

A first lower active contact 21 may be disposed in the second lower insulating layer 20 and may be connected to the lower source/drain pattern SD1 of the first active region AR1. The first lower active contact 21 may be disposed at a side of the first word line WL1. In detail, the first lower active contact 21 may extend in the third direction D3 from a bottom surface of the second lower insulating layer 20 into the second lower insulating layer 20, the first lower insulating layer 10, the substrate 100, and a portion of the lower source/drain pattern SD1 of the first active region AR1. A top surface of the first lower active contact 21 may be in the lower source/drain pattern SD1 of the first active region AR1.

The first lower active separation structure 21s may extend around the first lower active contact 21. However, in an embodiment, the first lower active separation structure 21s may be omitted, unlike the illustrated structure. The first lower active contact 21 may be electrically and selectively connected to the lower source/drain pattern SD1 of the first active region AR1.

A second lower active contact 31 may be disposed in the third lower insulating layer 30 and may be electrically connected to the lower source/drain pattern SD1 of the first active region AR1. The second lower active contact 31 may be disposed at an opposite side of the first word line WL1 where the first lower active contact 21 is not disposed. In detail, the second lower active contact 31 may extend in the third direction D3 from the bottom surface of the third lower insulating layer 30 into the third lower insulating layer 30, the second lower insulating layer 20, the first lower insulating layer 10, the substrate 100, and a portion of the lower source/drain pattern SD1 of the first active region AR1. A top surface of the second lower active contact 31 may be in the lower source/drain pattern SD1 of the first active region AR1.

A second lower active separation structure 31s may extend around the second lower active contact 31. However, the second lower active separation structure 31s may be omitted, unlike the illustrated structure. The second lower active contact 31 may be electrically and selectively connected to the lower source/drain pattern SD1 of the first active region AR1.

A third lower active contact 41 may extend in the third direction D3 from the bottom surface 100b of the substrate 100 and may be connected to the lower source/drain pattern SD1 of the third active region AR3. The third lower active contact 41 may be disposed at a side of the second word line WL2. In detail, the third lower active contact 41 may extend in the third direction D3 from the bottom surface 100b of the substrate 100 into the substrate 100 and a portion of the lower source/drain pattern SD1 of the third active region AR3. A top surface of the third lower active contact 41 may be in the lower source/drain pattern SD1 of the third active region AR3.

A third lower active separation structure 41s may extend around the third lower active contact 41. However, in an embodiment, the third lower active separation structure 41s may be omitted, unlike the illustrated structure. The third lower active contact 41 may be electrically and selectively connected to the lower source/drain pattern SD1 of the third active region AR3.

A fourth lower active contact 51 may be disposed in the third lower insulating layer 30 and may be electrically connected to the lower source/drain pattern SD1 of the third active region AR3. The fourth lower active contact 51 may be disposed at an opposite side of the second word line WL2 where the third lower active contact 41 is not disposed. In detail, the fourth lower active contact 51 may extend in the third direction D3 from the bottom surface of the third lower insulating layer 30 into the third lower insulating layer 30, the second lower insulating layer 20, the first lower insulating layer 10, the substrate 100, and a portion of the lower source/drain pattern SD1 of the third active region AR3. A top surface of the fourth lower active contact 51 may be in the lower source/drain pattern SD1 of the third active region AR3.

A fourth lower active separation structure 51s may extend around the fourth lower active contact 51. However, in an embodiment, the fourth lower active separation structure 51s may be omitted, unlike the illustrated structure. The fourth lower active contact 51 may be electrically and selectively connected to the lower source/drain pattern SD1 of the third active region AR3.

The first to fourth lower active contacts 21, 31, 41, and 51 may be formed of or include a doped semiconductor material and/or a metallic material. The metallic material may be selected from the group consisting of copper (Cu), aluminum (Al), ruthenium (Ru), cobalt (Co), tungsten (W), and molybdenum (Mo). The first to fourth lower active separation structures 21s, 31s, 41s, and 51s may be formed of or include at least one of silicon-based insulating materials (e.g., silicon oxide and silicon nitride).

The magnetic tunnel junction pattern MTJ may be disposed in the second lower insulating layer 20. The magnetic tunnel junction pattern MTJ may be configured to have substantially the same features as the magnetic tunnel junction pattern MTJ described with reference to FIGS. 3 and 4A to 4E. The magnetic tunnel junction pattern MTJ may not be vertically overlapped with the third lower active contact 41.

A lower interconnection line 131d and a lower interconnection contact 132d may be disposed in the first lower insulating layer 10. In detail, the lower interconnection line 131d and the lower interconnection contact 132d may be disposed between the magnetic tunnel junction pattern MTJ and the third lower active contact 41. The lower interconnection line 131d may be in contact with the third lower active contact 41 and the lower interconnection contact 132d. The lower interconnection contact 132d may be in contact with the magnetic tunnel junction pattern MTJ. For example, the magnetic tunnel junction pattern MTJ may be connected to the lower source/drain patterns SD1 of the third active region AR3 through the lower interconnection contact 132d, the lower interconnection line 131d, and the third lower active contact 41. When viewed in a plan view, the lower interconnection line 131d may have a rectangular shape or the shape of letter ‘L’.

The spin-orbit torque line SOT may be disposed in the third lower insulating layer 30. The spin-orbit torque line SOT may be in contact with the magnetic tunnel junction pattern MTJ and the first lower active contact 21. The spin-orbit torque line SOT may be a bar-shaped pattern that extends in the second direction D2.

The bit line contact BC may be disposed in the third lower insulating layer 30 to electrically connect the spin-orbit torque line SOT to the lower bit line BLd. The second and fourth lower active contacts 31 and 51 may be in electrical contact with the lower source line SLd.

In the embodiment of FIGS. 26, 27A, and 27B, the first to fourth upper active contacts 142, 152, 162, and 172 may be electrically connected to the upper source/drain patterns SD2 of the second and fourth active regions AR2 and AR4 serving as the upper transistors. In addition, the first to fourth lower active contacts 21, 31, 41, and 51 may be electrically connected to the lower source/drain patterns SD1 of the first and third active regions AR1 and AR3 serving as the lower transistors. Thus, it may be possible to increase a degree of freedom of the interconnection structure. In addition, by virtue of the upper and lower interconnection lines 131t and 131d and the upper and lower interconnection contacts 132t and 132d, it may be possible to increase a degree of freedom in placing the magnetic tunnel junction pattern MTJ.

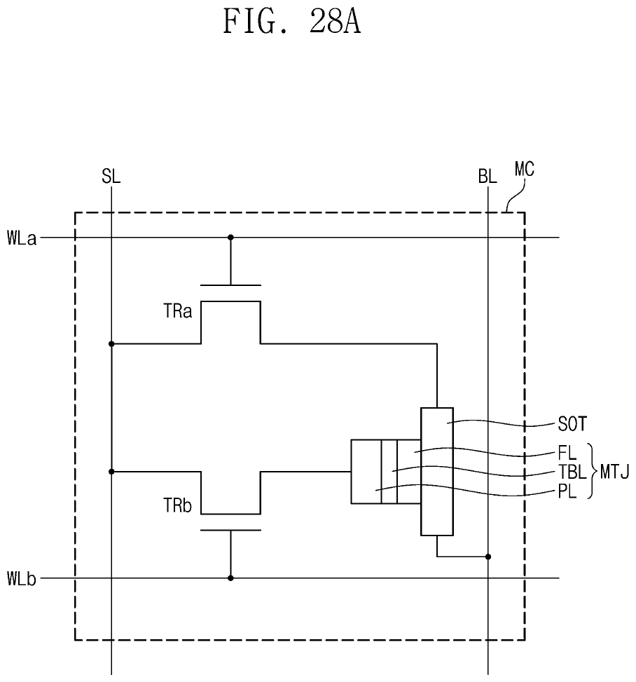

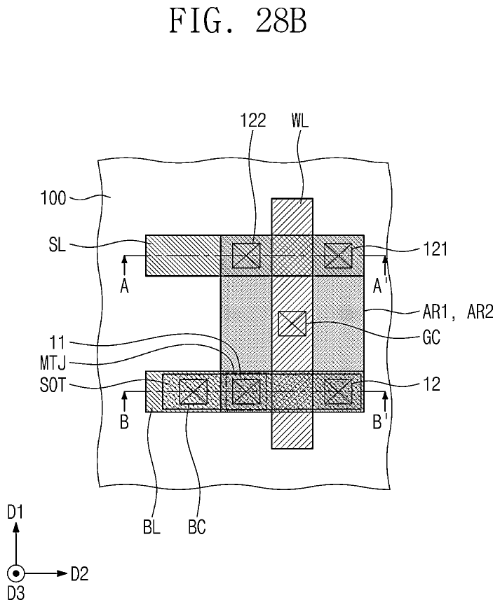

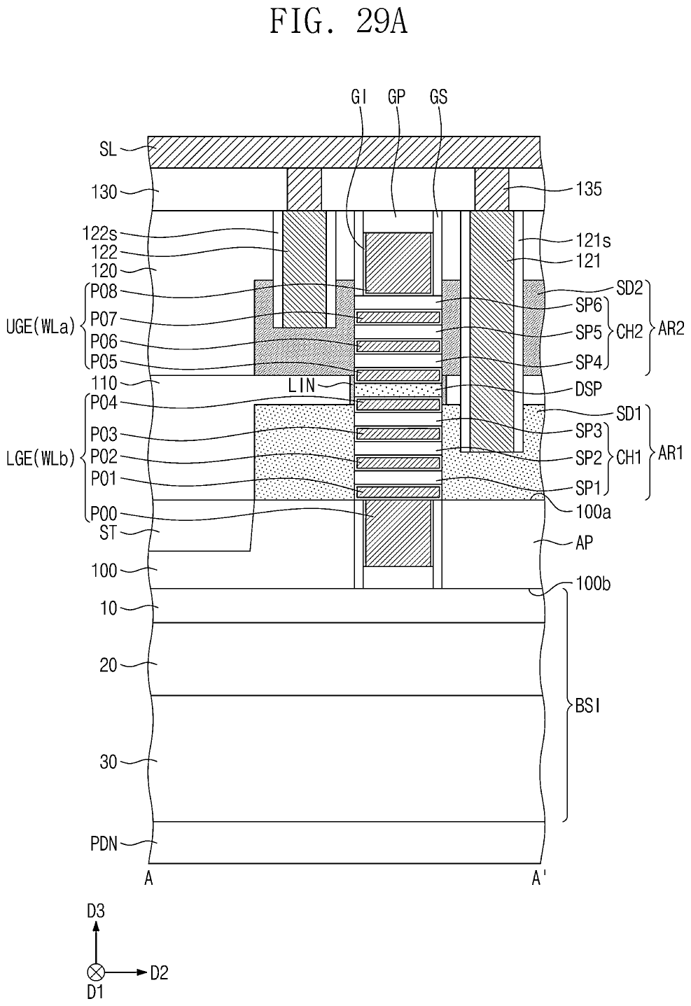

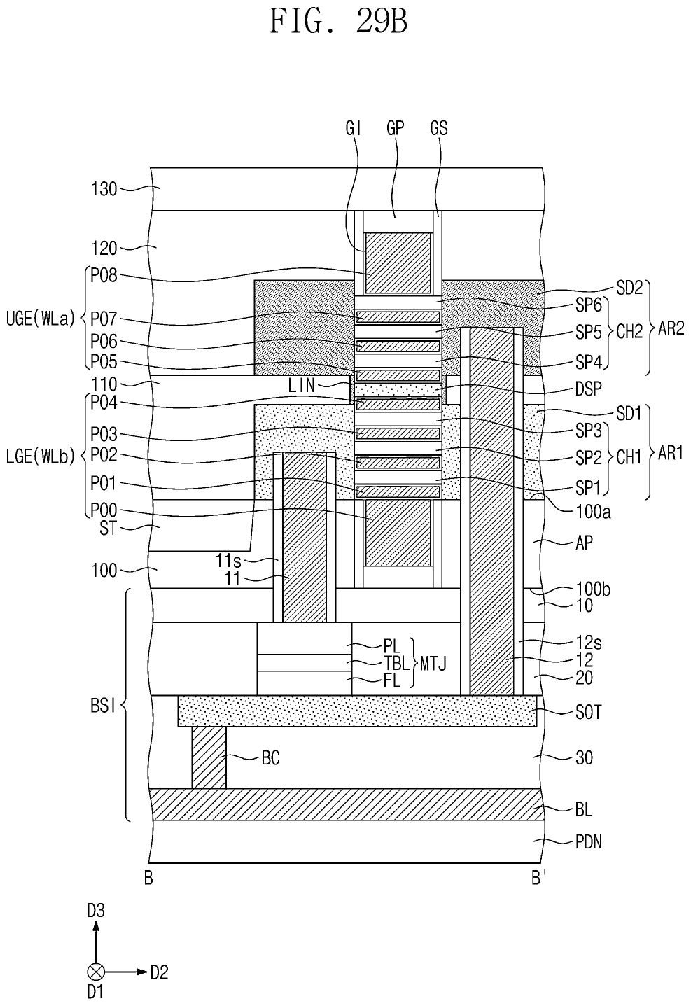

FIG. 28A is a circuit diagram schematically illustrating a memory cell of a magnetic memory device according to an embodiment of the inventive concept. FIG. 28B is a plan view illustrating the magnetic memory device of FIG. 28A. FIGS. 29A and 29B are cross-sectional views taken along lines A-A′ and B-B′ of FIG. 28B, respectively. For concise description, a previously described element may be identified by the same reference number without repeating an overlapping description thereof.

Referring to FIG. 28A, the upper transistor TRa of the memory cell MC may be electrically connected to an upper word line WLa (e.g., a gate terminal of the upper transistor Tra may be connected to the upper word line WLa). The lower transistor TRb of the memory cell MC may be electrically connected to a lower word line WLb. For example, unlike the afore-described embodiment, the gate may be provided to have a divided structure.

The lower gate electrode LGE may extend in the third direction D3 into the substrate 100. In detail, the lower gate electrode LGE may be disposed on the lower channel pattern CH1 of the first active region AR1. The lower gate electrode LGE may include the first portion PO1 interposed between the active pattern AP and the first semiconductor pattern SP1, the second portion PO2 interposed between the first semiconductor pattern SP1 and the second semiconductor pattern SP2, the third portion PO3 interposed between the second semiconductor pattern SP2 and the third semiconductor pattern SP3, and the fourth portion PO4 interposed between the third semiconductor pattern SP3 and the dummy channel pattern DSP and may further include a buried portion PO0 extending into the substrate 100.

The upper gate electrode UGE may be disposed on the upper channel pattern CH2. The upper gate electrode UGE may be configured to have substantially the same features as the upper gate electrode UGE described with reference to FIGS. 3 and 4A to 4E.

The upper gate electrode UGE may correspond to the upper word line WLa of FIG. 28A. The lower gate electrode LGE may correspond to the lower word line WLb of FIG. 28A.

In the embodiment of FIGS. 28A, 28B, 29A, and 29B, since the upper transistor and the lower transistor are separated from each other, it may be possible to increase a degree of freedom in a method of operating a cell. Furthermore, both of the lower and upper transistors may be the NMOSFETs, and in this case, the cell may be operated with an increased operation speed.

According to an embodiment of the inventive concept, lower source/drain patterns and upper source/drain patterns may be vertically stacked to constitute a lower transistor and an upper transistor, respectively. Thus, it may be possible to increase an integration density of the magnetic memory device.

Furthermore, by placing a magnetic tunnel junction pattern and a spin-orbit torque line on a rear surface of a substrate, it may be possible to reduce complexity of an interconnection structure.

In addition, an interlayer interconnection layer may be used to increase a degree of freedom in disposing a magnetic tunnel junction pattern.

While example embodiments of the inventive concept have been particularly shown and described, it will be understood by one of ordinary skill in the art that variations in form and detail may be made therein without departing from the spirit and scope of the attached claims.

What is claimed is:

1. A magnetic memory device, comprising:
a substrate having a top surface and a bottom surface, which are opposite to each other;
a first active region on the top surface of the substrate, the first active region comprising a lower channel pattern and a lower source/drain pattern connected to the lower channel pattern;
a second active region stacked on the first active region in a third direction perpendicular to the top surface of the substrate, the second active region comprising an upper channel pattern and an upper source/drain pattern connected to the upper channel pattern;
a gate electrode provided on the lower and upper channel patterns and extending in a first direction parallel to the top surface of the substrate;
a lower interconnection layer on the bottom surface of the substrate;
a magnetic tunnel junction pattern and a spin-orbit torque line in the lower interconnection layer;
a first lower contact extending in a portion of the lower interconnection layer and the substrate and connecting the lower source/drain pattern to the magnetic tunnel junction pattern; and
a second lower contact extending in a portion of the lower interconnection layer, the substrate, and the lower source/drain pattern and connecting the upper source/drain pattern to the spin-orbit torque line.

2. The magnetic memory device of claim 1, further comprising a lower separation structure extending around a side surface of the second lower contact;
wherein the second lower contact is electrically separated from the lower source/drain pattern by the lower separation structure.

3. The magnetic memory device of claim 1, wherein the spin-orbit torque line has a bar-shaped pattern extending in a second direction parallel to the top surface of the substrate and crossing the first direction,
wherein the magnetic memory device further comprises:
a bit line in the lower interconnection layer and extending in the second direction; and
a bit line contact electrically connecting the bit line to the spin-orbit torque line.

4. The magnetic memory device of claim 1, further comprising:
a first interlayer insulating layer on the lower source/drain pattern;
a second interlayer insulating layer on the first interlayer insulating layer and the upper source/drain pattern;
a first upper contact extending into the second interlayer insulating layer, the upper source/drain pattern, and a portion of the first interlayer insulating layer and electrically connected to the lower source/drain pattern; and
a second upper contact extending into a portion of the second interlayer insulating layer and electrically connected to the upper source/drain pattern.

5. The magnetic memory device of claim 4, further comprising:
a third interlayer insulating layer on the second interlayer insulating layer;
a source line on the third interlayer insulating layer and extending in the second direction; and
source contacts electrically connecting the source line to the first and second upper contacts, respectively.

6. The magnetic memory device of claim 4, further comprising an upper separation structure extending around a side surface of the first upper contact,
wherein the first upper contact is electrically separated from the upper source/drain pattern by the upper separation structure.

7. The magnetic memory device of claim 1, wherein the magnetic tunnel junction pattern is in contact with the spin-orbit torque line and at least partially overlaps the first lower contact in the third direction.

8. The magnetic memory device of claim 1, further comprising an interlayer interconnection line and an interlayer interconnection contact between the magnetic tunnel junction pattern and the first lower contact.

9. The magnetic memory device of claim 8, wherein the magnetic tunnel junction pattern does not overlap the first lower contact in the third direction.

10. The magnetic memory device of claim 9, wherein the spin-orbit torque line comprises:
a first portion extending in the second direction and having a first surface and a second surface, which are opposite to each other in the first direction; and
a second portion extending from the second surface of the first portion in the first direction.

11. The magnetic memory device of claim 1, further comprising:
a third active region spaced apart from the first active region in the first direction, the third active region comprising the lower channel pattern and the lower source/drain pattern;
a fourth active region stacked on the third active region in the third direction and spaced apart from the second active region in the first direction, the fourth active region comprising the upper channel pattern and the upper source/drain pattern;
a first interlayer insulating layer on the lower source/drain patterns of the first and third active regions;
a second interlayer insulating layer on the first interlayer insulating layer and on the upper source/drain patterns of the second and fourth active regions;
a third interlayer insulating layer on the second interlayer insulating layer;
first upper contacts extending into the second interlayer insulating layer, the upper source/drain patterns of the second and fourth active regions, and a portion of the first interlayer insulating layer and electrically connected to the lower source/drain patterns of the first and third active regions, respectively;
second upper contacts extending into a portion of the second interlayer insulating layer and electrically connected to the upper source/drain patterns of the second and fourth active regions, respectively;
source contacts electrically connected to the first and second upper contacts, respectively; and
a source line on the third interlayer insulating layer and extending in the second direction,
wherein the source line extends in the first direction and is electrically connected in common to the source contacts.

12. The magnetic memory device of claim 1, wherein each of the lower and upper channel patterns comprises a plurality of semiconductor patterns, which are stacked to be spaced apart from each other in the third direction, and
the gate electrode extends around each of the semiconductor patterns.

13. The magnetic memory device of claim 1, further comprising a dummy channel pattern between the lower and upper channel patterns,
wherein the dummy channel pattern comprises a semiconductor material or a silicon-based insulating material.

14. A magnetic memory device, comprising:
a substrate having a top surface and a bottom surface, which are opposite to each other;
a lower source/drain pattern on the top surface of the substrate;
an upper source/drain pattern stacked on the lower source/drain pattern and vertically spaced apart from the lower source/drain pattern, the lower and upper source/drain patterns at least partially vertically overlapping each other;
an interlayer insulating layer on the lower and upper source/drain patterns;
a source line on the interlayer insulating layer;
a lower interconnection layer on the bottom surface of the substrate;
a magnetic tunnel junction pattern and a spin-orbit torque line in the lower interconnection layer; and
a bit line in the lower interconnection layer and spaced apart from the bottom surface of the substrate with the magnetic tunnel junction pattern and the spin-orbit torque line therebetween,
wherein the source line and the bit line are spaced apart from each other in a first direction parallel to the top surface of the substrate and extend in a second direction parallel to the top surface of the substrate and crossing the first direction, when viewed in a plan view, and
the spin-orbit torque line extends in the second direction and at least partially vertically overlaps the bit line.

15. The magnetic memory device of claim 14, further comprising:
a first lower contact extending into a portion of the lower interconnection layer and the substrate and electrically connecting the lower source/drain pattern to the magnetic tunnel junction pattern;
a second lower contact extending into a portion of the lower interconnection layer, the substrate, and the lower source/drain pattern and electrically connecting the upper source/drain pattern to the spin-orbit torque line; and
a lower separation structure extending around a side surface of the second lower contact,
wherein the second lower contact is electrically separated from the lower source/drain pattern by the lower separation structure.

16. The magnetic memory device of claim 15, wherein the magnetic tunnel junction pattern is in contact with the spin-orbit torque line and at least partially vertically overlaps the first lower contact.

17. The magnetic memory device of claim 15, further comprising an interlayer interconnection line and an interlayer interconnection contact, which are between the magnetic tunnel junction pattern and the first lower contact.

18. A magnetic memory device, comprising:
a substrate having a top surface and a bottom surface, which are opposite to each other, and comprising an active pattern;
a first active region on the active pattern, the first active region comprising a lower channel pattern and a lower source/drain pattern connected to the lower channel pattern;
a second active region stacked on the first active region in a third direction perpendicular to the top surface of the substrate, the second active region comprising an upper channel pattern and an upper source/drain pattern connected to the upper channel pattern;
a gate electrode on the lower and upper channel patterns and extending in a first direction parallel to the top surface of the substrate;
a lower interconnection layer including a first lower insulating layer, a second lower insulating layer, and a third lower insulating layer, which are sequentially stacked in the third direction on the bottom surface of the substrate;
a bit line in the third lower insulating layer;
a first lower contact extending into the first lower insulating layer and the substrate;
a second lower contact extending into the first and second lower insulating layers, the substrate, and the lower source/drain pattern;
a magnetic tunnel junction pattern in the second lower insulating layer and electrically connected to the first lower contact; and
a spin-orbit torque line in the third lower insulating layer and electrically connected to the second lower contact and the magnetic tunnel junction pattern,
wherein the magnetic tunnel junction pattern and the spin-orbit torque line are between the bottom surface of the substrate and the bit line.

19. The magnetic memory device of claim 18, further comprising a lower separation structure extending around a side surface of the second lower contact;
wherein the second lower contact is electrically separated from the lower source/drain pattern by the lower separation structure.

20. The magnetic memory device of claim 18, further comprising:
a first interlayer insulating layer on the lower source/drain pattern;
a second interlayer insulating layer on the first interlayer insulating layer and the upper source/drain pattern;
a first upper contact extending into the second interlayer insulating layer, the upper source/drain pattern, and a portion of the first interlayer insulating layer and electrically connected to the lower source/drain pattern;
a second upper contact extending into a portion of the second interlayer insulating layer and electrically connected to the upper source/drain pattern; and
an upper separation structure extending around a side surface of the first upper contact,
wherein the first upper contact is electrically separated from the upper source/drain pattern by the upper separation structure.
